(19) United States
(12) Patent Application Publication
(10) Pub. No.: US 2025/0275459 A1
(43) Pub. Date: Aug. 28, 2025

(54) PHOTOELECTRIC CONVERSION ELEMENT

(71) Applicant: SUMITOMO CHEMICAL COMPANY, LIMITED, Chuo-ku, Tokyo (JP)

(72) Inventor: Yuya ONITSUKA, Tsukuba-shi, Ibaraki (JP)

(73) Assignee: SUMITOMO CHEMICAL COMPANY, LIMITED, Chuo-ku, Tokyo (JP)

(21) Appl. No.: 18/688,557

(22) PCT Filed: Sep. 16, 2022
(86) PCT No.: PCT/JP2022/034733

§ 371 Date: Aug. 7, 2024

(30) Foreign Application Priority Data
Sep. 30, 2021 (JP) 2021-161911

(51) Int. Cl. H10K 85/10; G01S 7/481; G01T 1/20; G06V 40/13; G06V 40/145; H10K 30/15; H10K 30/60; H10K 39/32; H10K 39/34; H10K 85/20; H10K 101/30; H10K 101/40

(52) U.S. Cl. CPC H10K 85/113; H10K 30/15; H10K 30/60; H10K 85/215; G01S 7/4816; G01T 1/20181; G06V 40/1318; G06V 40/145; H10K 39/32; H10K 39/34; H10K 2101/30; H10K 2101/40

(57) ABSTRACT

A photoelectric conversion element includes a pair of electrodes; an active layer provided between the pair of electrodes and including a p-type semiconductor (P); and a buffer layer provided between one of the pair of electrodes and the active layer and including a dielectric (D), in which the dielectric (D) has a band gap of 4 eV or more and a relative permittivity of 20 or more, and the photoelectric conversion element satisfies the following Expression (1).

$$Ec - E ( L ) > 0.8 eV \qquad ( 1 )$$

In Expression (1), Ec represents an energy level at a lower end of a conduction band of the dielectric (D), and E(L) represents a LUMO energy level of the p-type semiconductor (P).

### TECHNICAL FIELD

The present invention relates to a photoelectric conversion element.

### BACKGROUND ART

A photoelectric conversion element is, for example, an extremely useful device from the viewpoint of energy saving and reduction of a carbon dioxide emission amount, and has attracted attention.

In the photoelectric conversion element, photoelectric conversion may occur and a current may flow even in a dark state where light is not emitted. In a case where a photoelectric conversion element is used as a photodetector (OPD), a dark current becomes noise and decreases an S/N ratio of photodetection, such that the dark current value has been reduced. For example, in the technique of Non-Patent Document 1, a metal oxide semiconductor such as nickel oxide, molybdenum oxide, vanadium oxide, or tungsten oxide is used in order to obtain an electron blocking effect.

### PRIOR ART DOCUMENTS

### Non-Patent Document

Non-Patent Document 1: Nanomaterials, 2021, 11 (6), 1404

### SUMMARY OF THE INVENTION

### Problems to be Solved by the Invention

The photoelectric conversion element may be heated in a step after being formed on a substrate or the like, for example, a step of being mounted on an imaging device. The photoelectric conversion element described in Non-Patent Document 1 has a problem that the dark current value significantly increases by being heated.

Therefore, there is a demand for a photoelectric conversion element in which an increase in dark current value due to heating is suppressed.

### Means for Solving the Problems

The present inventors have intensively studied to solve the above problems, and have completed the present invention.

The present invention provides the following.

[1] A photoelectric conversion element including:
a pair of electrodes;
an active layer provided between the pair of electrodes and including a p-type semiconductor (P); and
a buffer layer provided between one of the pair of electrodes and the active layer and including a dielectric (D),
in which the dielectric (D) has a band gap of 4 eV or more and a relative permittivity of 20 or more, and
the photoelectric conversion element satisfies the following Expression (1).

$$Ec - E ( L ) > 0.8 eV \qquad ( 1 )$$

(In Expression (1), Ec represents an energy level at a lower end of a conduction band of the dielectric (D), and E(L) represents a LUMO energy level of the p-type semiconductor (P).)
   [2] The photoelectric conversion element according to [1], in which the dielectric (D) is an oxide including one or more selected from the group consisting of hafnium oxide, zirconium oxide, and tantalum oxide.
   [3] The photoelectric conversion element according to [1] or [2], in which the p-type semiconductor (P) is a conjugated polymer compound.
   [4] The photoelectric conversion element according to any one of [1] to [3], in which the p-type semiconductor (P) is a polymer compound containing a structural unit represented by the following Formula (I) and/or a structural unit represented by the following Formula (II).

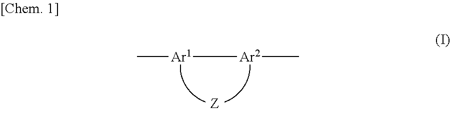

(In Formula (I), Ar¹ and Ar² each independently represent a trivalent aromatic heterocyclic group which may have a substituent, and Z represents a group represented by any one of the following Formulas (Z-1) to (Z-7).

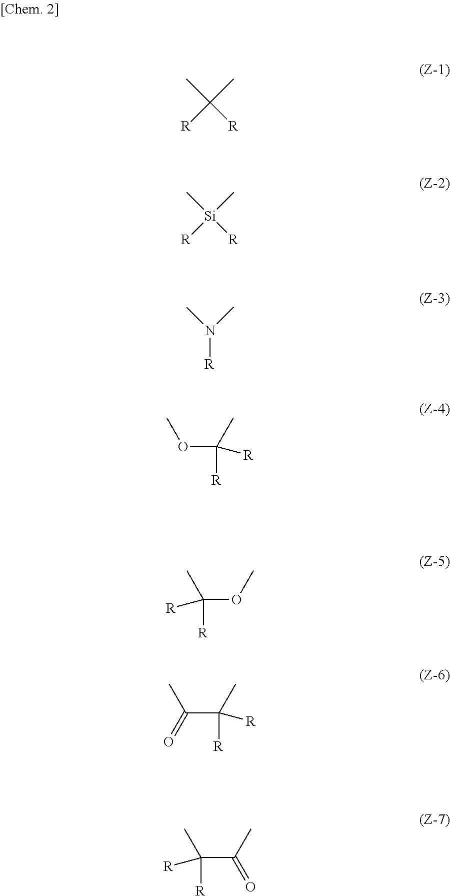

(In Formulas (Z-1) to (Z-7), R represents
a hydrogen atom,
a halogen atom,
an alkyl group which may have a substituent,
a cycloalkyl group which may have a substituent,
an alkenyl group which may have a substituent,
a cycloalkenyl group which may have a substituent,
an alkynyl group which may have a substituent,
a cycloalkynyl group which may have a substituent,
an aryl group which may have a substituent,
an alkyloxy group which may have a substituent,
a cycloalkyloxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an imine residue which may have a substituent,
an amide group which may have a substituent,
an acid imide group which may have a substituent,
a substituted oxycarbonyl group which may have a substituent,
a cyano group,
a nitro group,
a group represented by —C(═O)—R^{c}, or
a group represented by —SO₂—R^{d}, and
R^{c} and R^{d} each independently represent
a hydrogen atom,
an alkyl group which may have a substituent,
a cycloalkyl group which may have a substituent,
an aryl group which may have a substituent,
an alkyloxy group which may have a substituent,
a cycloalkyloxy group which may have a substituent,
an aryloxy group which may have a substituent, or
a monovalent heterocyclic group which may have a substituent, and
in Formulas (Z-1) to (Z-7), when the number of R's is two, the two R's may be the same as or different from each other.))

[Chem. 3]

—Ar³— (II)
(In Formula (II), Ar³ represents a divalent aromatic heterocyclic group.)
   [5] The photoelectric conversion element according to any one of [1] to [4], in which the photoelectric conversion element is used for a photodetector.

### Effect of the Invention

According to the present invention, there is provided a photoelectric conversion element in which an increase in dark current value due to heating is suppressed.

### BRIEF DESCRIPTION OF THE DRAWINGS

FIG. 1 is an energy diagram schematically illustrating an action in a case where a photoelectric conversion element according to an embodiment of the present invention is set in a dark state.

FIG. 2 is an energy diagram schematically illustrating an action in a case where a photoelectric conversion element according to an embodiment of the present invention is irradiated with light.

FIG. 3 is a diagram schematically illustrating an energy level of a constituent element of a photoelectric conversion element according to an embodiment of the present invention.

FIG. 4 is a view schematically illustrating a configuration example of a photoelectric conversion element.

FIG. 5 is a view schematically illustrating a configuration example of an image detection unit.

FIG. 6 is a view schematically illustrating a configuration example of a fingerprint detection unit.

FIG. 7 is a view schematically illustrating a configuration example of an image detection unit for an X-ray imaging device.

FIG. 8 is a view schematically illustrating a configuration example of a vein detection unit for a vein authentication device.

FIG. 9 is a view schematically illustrating a configuration example of an image detection unit for an indirect time-of-flight (TOF) type distance measuring device.

### MODE FOR CARRYING OUT THE INVENTION

Hereinafter, embodiments of the present invention will be described with reference to the drawings. Note that the drawings merely schematically illustrate the shape, size, and arrangement of constituent elements to the extent that the invention can be understood. The present invention is not limited by the following description, and each constituent element can be appropriately changed without departing from the gist of the present invention. In the drawings used in the following description, the same constituent elements are denoted by the same reference numerals, and redundant description may be omitted. In addition, the configuration according to the embodiment of the present invention is not necessarily used in the arrangement of the illustrated examples.

### 1. Description of Common Terms

In the present specification, a “polymer compound” means a polymer having a molecular weight distribution and a number average molecular weight of 1×10³ or more and 1×10⁸ or less in terms of polystyrene. A structural unit contained in the polymer compound is 100 mol % in total.

In the present specification, a “structural unit” means one or more units present in a polymer compound.

In the present specification, a “hydrogen atom” may be a light hydrogen atom or a heavy hydrogen atom.

In the present specification, examples of a “halogen atom” include a fluorine atom, a chlorine atom, a bromine atom, and an iodine atom.

An aspect of “which may have a substituent” includes both aspects of a case where all hydrogen atoms constituting a compound or group are unsubstituted and a case where some or all of one or more hydrogen atoms are substituted with a substituent.

Examples of the substituent include a halogen atom, an alkyl group, a cycloalkyl group, an alkenyl group, a cycloalkenyl group, an alkynyl group, a cycloalkynyl group, an alkyloxy group, a cycloalkyloxy group, an alkylthio group, a cycloalkylthio group, an aryl group, an aryloxy group, an arylthio group, a monovalent heterocyclic group, a substituted amino group, an acyl group, an imine residue, an amide group, an acid imide group, a substituted oxycarbonyl group, a cyano group, an alkylsulfonyl group, and a nitro group.

In the present specification, an “alkyl group” may have a substituent. The “alkyl group” may have any of a linear shape and a branched shape unless otherwise specified. The number of carbon atoms in a linear alkyl group is usually 1 to 50, preferably 1 to 30, and more preferably 1 to 20, without including the number of carbon atoms in the substituent. The number of carbon atoms in a branched alkyl group is usually 3 to 50, preferably 3 to 30, and more preferably 4 to 20, without including the number of carbon atoms in the substituent.

Specific examples of the alkyl group include unsubstituted alkyl groups such as a methyl group, an ethyl group, an n-propyl group, an isopropyl group, an n-butyl group, an isobutyl group, a tert-butyl group, an n-pentyl group, an isoamyl group, a 2-ethylbutyl group, an n-hexyl group, an n-heptyl group, an n-octyl group, a 2-ethylhexyl group, a 3-n-propylheptyl group, an n-decyl group, a 3,7-dimethyloctyl group, a 2-ethyloctyl group, a 2-n-hexyl-decyl group, an n-dodecyl group, a tetradecyl group, a hexadecyl group, an octadecyl group, and an icosyl group; and substituted alkyl groups such as a cyclohexylmethyl group, a cyclohexylethyl group, a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di)-n-hexylphenyl)propyl group, and a 6-ethyloxyhexyl group.

The “cycloalkyl group” may be a monocyclic group or a polycyclic group. The cycloalkyl group may have a substituent. The number of carbon atoms of the cycloalkyl group is usually 3 to 30 and preferably 3 to 20 without including the number of carbon atoms of the substituent.

Examples of the cycloalkyl group include alkyl groups having no substituent, such as a cyclopentyl group, a cyclohexyl group, a cycloheptyl group, and an adamantyl group, and a group in which a hydrogen atom in these groups is substituted with a substituent such as an alkyl group, an alkyloxy group, an aryl group, or a fluorine atom.

Specific examples of a cycloalkyl group having a substituent include a methylcyclohexyl group and an ethylcyclohexyl group.

The “alkenyl group” may be linear or branched. The alkenyl group may have a substituent. The number of carbon atoms of the alkenyl group is usually 2 to 30 and preferably 2 to 20 without including the number of carbon atoms of the substituent.

Examples of the alkenyl group include alkenyl groups having no substituent, such as a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, and a 7-octenyl group, and a group in which a hydrogen atom in these groups is substituted with a substituent such as an alkyloxy group, an aryl group, or a fluorine atom.

The “cycloalkenyl group” may be a monocyclic group or a polycyclic group. The cycloalkenyl group may have a substituent. The number of carbon atoms of the cycloalkenyl group is usually 3 to 30 and preferably 3 to 20 without including the number of carbon atoms of the substituent.

Examples of the cycloalkenyl group include cycloalkenyl groups having no substituent, such as a cyclohexenyl group, and a group in which a hydrogen atom in these groups is substituted with a substituent such as an alkyl group, an alkyloxy group, an aryl group, or a fluorine atom.

Examples of a cycloalkenyl group having a substituent include a methylcyclohexenyl group and an ethylcyclohexenyl group.

The “alkynyl group” may be linear or branched. The alkynyl group may have a substituent. The number of carbon atoms of the alkynyl group is usually 2 to 30 and preferably 2 to 20 without including the number of carbon atoms of the substituent.

Examples of the alkynyl group include alkynyl groups having no substituent, such as an ethynyl group, a 1-propynyl group, a 2-propynyl group, a 2-butynyl group, a 3-butynyl group, a 3-pentynyl group, a 4-pentynyl group, a 1-hexynyl group, and a 5-hexynyl group, and a group in which a hydrogen atom in these groups is substituted with a substituent such as an alkyloxy group, an aryl group, or a fluorine atom.

The “cycloalkynyl group” may be a monocyclic group or a polycyclic group. The cycloalkynyl group may have a substituent. The number of carbon atoms of the cycloalkynyl group is usually 4 to 30 and preferably 4 to 20 without including the number of carbon atoms of the substituent.

Examples of the cycloalkynyl group include cycloalkynyl groups having no substituent, such as a cyclohexenyl group, and a group in which a hydrogen atom in these groups is substituted with a substituent such as an alkyl group, an alkyloxy group, an aryl group, or a fluorine atom.

Examples of a cycloalkynyl group having a substituent include a methylcyclohexanyl group and an ethylcyclohexenyl group.

The “alkyloxy group” may be linear or branched. The alkyloxy group may have a substituent. The number of carbon atoms of the alkyloxy group is usually 1 to 30 and preferably 1 to 20 without including the number of carbon atoms of the substituent.

Examples of the alkyloxy group include alkyloxy groups having no substituent, such as a methoxy group, an ethoxy group, an n-propyloxy group, an isopropyloxy group, an n-butyloxy group, an isobutyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, a 3,7-dimethyloctyloxy group, a 3-heptyldodecyloxy group, and a lauroyloxy group, and a group in which a hydrogen atom in these groups is substituted with a substituent such as an alkyloxy group, an aryl group, or a fluorine atom.

A cycloalkyl group included in the “cycloalkyloxy group” may be a monocyclic group or a polycyclic group. The cycloalkyloxy group may have a substituent. The number of carbon atoms of the cycloalkyloxy group is usually 3 to 30 and preferably 3 to 20 without including the number of carbon atoms of the substituent.

Examples of the cycloalkyloxy group include cycloalkyloxy groups having no substituent, such as a cyclopentyloxy group, a cyclohexyloxy group, and a cycloheptyloxy group, and a group in which a hydrogen atom in these groups is substituted with a substituent such as a fluorine atom or an alkyl group.

The “alkylthio group” may be linear or branched. The alkylthio group may have a substituent. The number of carbon atoms of the alkylthio group is usually 1 to 30 and preferably 1 to 20 without including the number of carbon atoms of the substituent.

Examples of an alkylthio group which may have a substituent include a methylthio group, an ethylthio group, an n-propylthio group, an isopropylthio group, an n-butylthio group, an isobutylthio group, a tert-butylthio group, an n-pentylthio group, an n-hexylthio group, an n-heptylthio group, an n-octylthio group, a 2-ethylhexylthio group, an n-nonylthio group, an n-decylthio group, a 3,7-dimethyloctylthio group, a 3-heptyldodecylthio group, a laurylthio group, and a trifluoromethylthio group.

A cycloalkyl group included in the “cycloalkylthio group” may be a monocyclic group or a polycyclic group. The cycloalkylthio group may have a substituent. The number of carbon atoms of the cycloalkylthio group is usually 3 to 30 and preferably 3 to 20 without including the number of carbon atoms of the substituent.

Examples of a cycloalkylthio group which may have a substituent include a cyclohexylthio group.

The “p-valent aromatic carbocyclic group” means a remaining atomic group obtained by removing p hydrogen atoms directly bonded to carbon atoms constituting a ring from an aromatic hydrocarbon which may have a substituent. The aromatic hydrocarbon also includes a compound having a fused ring, and a compound in which two or more selected from the group consisting of an independent benzene ring and a fused ring are bonded directly or via a divalent group such as vinylene. The p-valent aromatic carbocyclic group may further have a substituent.

The “aryl group” means a monovalent aromatic carbocyclic group. The aryl group may have a substituent. The number of carbon atoms of the aryl group is usually 6 to 60 and preferably 6 to 48 without including the number of carbon atoms of the substituent.

Examples of the aryl group include aryl groups having no substituent, such as a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, and a 4-phenylphenyl group, and a group in which a hydrogen atom in these groups is substituted with a substituent such as an alkyl group, an alkyloxy group, an aryl group, or a fluorine atom.

The “aryloxy group” may have a substituent. The number of carbon atoms of the aryloxy group is usually 6 to 60 and preferably 6 to 48 without including the number of carbon atoms of the substituent.

Examples of the aryloxy group include aryloxy groups having no substituent, such as a phenoxy group, a 1-naphthyloxy group, a 2-naphthyloxy group, a 1-anthracenyloxy group, a 9-anthracenyloxy group, and a 1-pyrenyloxy group, and a group in which a hydrogen atom in these groups is substituted with a substituent such as an alkyl group, an alkyloxy group, or a fluorine atom.

The “arylthio group” may have a substituent. The number of carbon atoms of the arylthio group is usually 6 to 60 and preferably 6 to 48 without including the number of carbon atoms of the substituent.

Examples of an arylthio group which may have a substituent include a phenylthio group, a C1-C12 alkyloxyphenylthio group, a C1-C12 alkylphenylthio group, a 1-naphthylthio group, a 2-naphthylthio group, and a pentafluorophenylthio group. The “C1-C12” indicates that the number of carbon atoms of a group described immediately after that is 1 to 12. Furthermore, the “Cm-Cn” indicates that the number of carbon atoms of a group described immediately after that is m to n. The same applies to the following.

The “p-valent heterocyclic group” (p represents an integer of 1 or more) means a remaining atomic group obtained by removing p hydrogen atoms among hydrogen atoms directly bonded to carbon atoms or heteroatoms constituting a ring from a heterocyclic compound which may have a substituent. A “p-valent aromatic heterocyclic group” is included in the “p-valent heterocyclic group”. The “p-valent aromatic heterocyclic group” means a remaining atomic group obtained by removing p hydrogen atoms among hydrogen atoms directly bonded to carbon atoms or heteroatoms constituting a ring from an aromatic heterocyclic compound which may have a substituent.

The aromatic heterocyclic compound includes a compound in which an aromatic ring is condensed to a heterocyclic ring even when the heterocyclic ring itself does not exhibit aromaticity, in addition to a compound in which a heterocyclic ring itself exhibits aromaticity.

Among the aromatic heterocyclic compounds, specific examples of the compound in which a heterocyclic ring itself exhibits aromaticity include oxadiazole, thiadiazole, thiazole, oxazole, thiophene, pyrrole, phosphole, furan, pyridine, pyrazine, pyrimidine, triazine, pyridazine, quinoline, isoquinoline, carbazole, and dibenzophosphole.

Among the aromatic heterocyclic compounds, specific examples of the compound in which an aromatic ring is fused to a heterocyclic ring even when the heterocyclic ring itself does not exhibit aromaticity include phenoxazine, phenothiazine, dibenzoborole, dibenzosilole, and benzopyran.

The p-valent heterocyclic group may have a substituent. The number of carbon atoms of the p-valent heterocyclic group is usually 2 to 60 and preferably 2 to 20 without including the number of carbon atoms of the substituent.

Examples of the monovalent heterocyclic group include a monovalent aromatic heterocyclic group (for example, a thienyl group, a pyrrolyl group, a furyl group, a pyridyl group, a quinolyl group, an isoquinolyl group, a pyrimidinyl group, and a triazinyl group), a monovalent non-aromatic heterocyclic group (for example, a piperidyl group and a piperazyl group), and a group in which a hydrogen atom in these groups is substituted with a substituent such as an alkyl group, an alkyloxy group, or a fluorine atom.

The “substituted amino group” means an amino group having a substituent. As the substituent of the amino group, an alkyl group, an aryl group, and a monovalent heterocyclic group are preferable. The number of carbon atoms of the substituted amino group is usually 1 to 30 without including the number of carbon atoms of the substituent.

Examples of the substituted amino group include a dialkylamino group (for example, a dimethylamino group and a diethylamino group), and a diarylamino group (for example, a diphenylamino group, a bis(4-methylphenyl)amino group, a bis(4-tert-butylphenyl)amino group, and a bis(3,5-di-tert-butylphenyl)amino group).

The “acyl group” may have a substituent. The number of carbon atoms of the acyl group is usually 2 to 20 and preferably 2 to 18 without including the number of carbon atoms of the substituent. Specific examples of the acyl group include an acetyl group, a propionyl group, a butyryl group, an isobutyryl group, a pivaloyl group, a benzoyl group, a trifluoroacetyl group, and a pentafluorobenzoyl group.

The “imine residue” means a remaining atomic group obtained by removing one hydrogen atom directly bonded to a carbon atom or a nitrogen atom constituting a carbon atom-nitrogen atom double bond from an imine compound. The “imine compound” means an organic compound having a carbon atom-nitrogen atom double bond in the molecule. Examples of the imine compound include aldimine, ketimine, and a compound in which a hydrogen atom bonded to a nitrogen atom constituting a carbon atom-nitrogen atom double bond in aldimine is substituted with a substituent such as an alkyl group.

The number of carbon atoms of the imine residue is usually 2 to 20 and preferably 2 to 18. Examples of the imine residue include a group represented by the following structural formula.

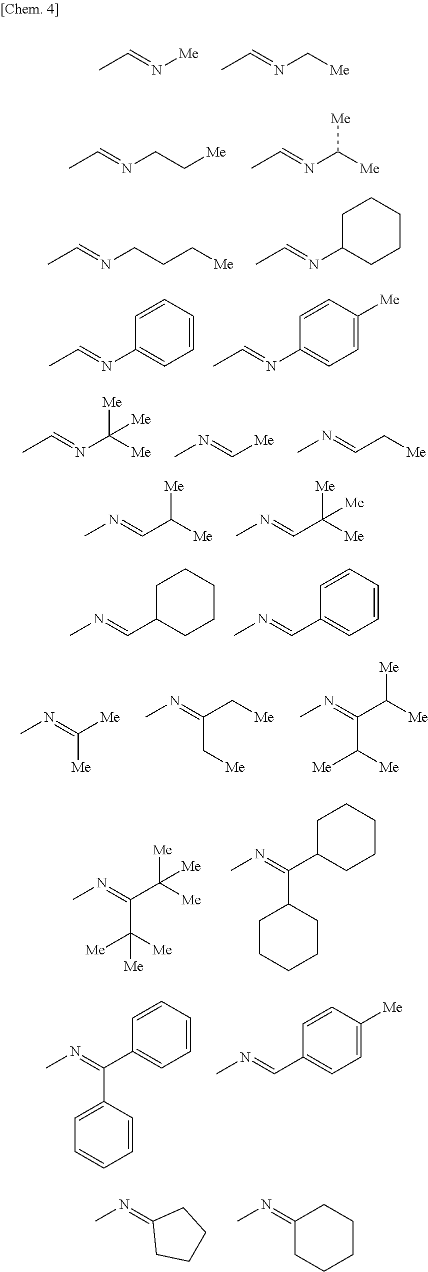

The “amide group” means a remaining atomic group obtained by removing one hydrogen atom bonded to a nitrogen atom from an amide. The number of carbon atoms of the amide group is usually about 1 to 20 and preferably 1 to 18. Specific examples of the amide group include a formamide group, an acetamide group, a propionamide group, a butyramide group, a benzamide group, a trifluoroacetamide group, a pentafluorobenzamide group, a diformamide group, a diacetamide group, a dipropylamide group, a dibutyramide group, a dibenzamide group, a ditrifluoroacetamide group, and a dipentafluorobenzamide group.

The “acid imide group” means a remaining atomic group obtained by removing one hydrogen atom bonded to a nitrogen atom from an acid imide. The number of carbon atoms of the acid imide group is usually 4 to 20. Specific examples of the acid imide group include a group shown below.

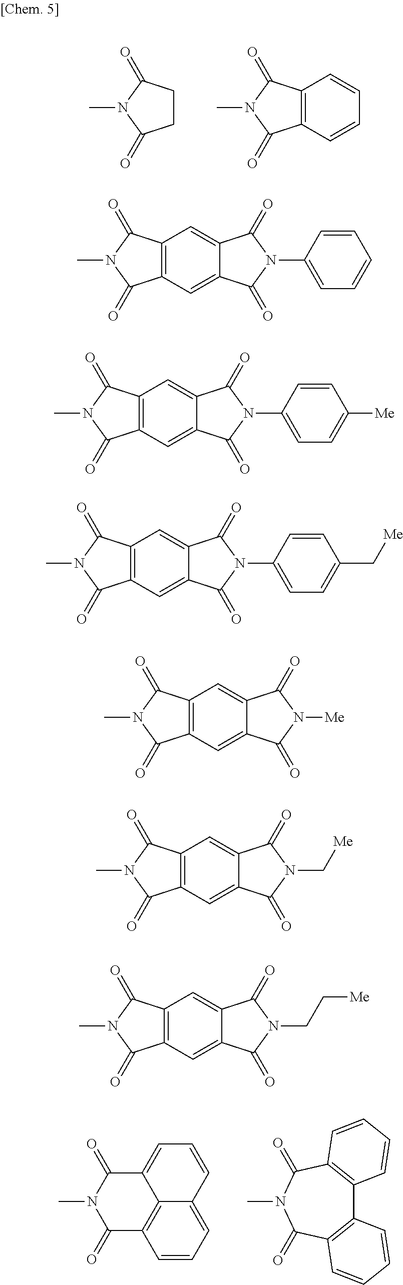

The “substituted oxycarbonyl group” means a group represented by R′—O—(C═O)—. Here, R′ represents an alkyl group, a cycloalkyl group, an aryl group, an arylalkyl group, or a monovalent heterocyclic group.

The number of carbon atoms of the substituted oxycarbonyl group is usually 2 to 60 and preferably 2 to 48.

Specific examples of the substituted oxycarbonyl group include a methoxycarbonyl group, an ethoxycarbonyl group, a propoxycarbonyl group, an isopropoxycarbonyl group, a butoxycarbonyl group, an isobutoxycarbonyl group, a tert-butyloxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, and a pyridyloxycarbonyl group.

The “alkylsulfonyl group” may be linear or branched. The alkylsulfonyl group may have a substituent. The number of carbon atoms in the alkylsulfonyl group is usually 1 to 30 without including the number of carbon atoms in the substituent. Specific examples of the alkylsulfonyl group include a methylsulfonyl group, an ethylsulfonyl group, and a dodecylsulfonyl group.

“*” attached to the chemical formula represents a bond.

The “π-conjugated system” means a system in which π electrons are delocalized over a plurality of bonds.

In the chemical formula, “Me” represents a methyl group, “Et” represents an ethyl group, and “Bu” represents a butyl group.

“HOMO” means the highest occupied molecular orbital. “LUMO” means the lowest unoccupied molecular orbital. The energy level of the HOMO and the energy level of the LUMO are defined with a vacuum level of 0 eV.

### 2. Outline of Photoelectric Conversion Element

A photoelectric conversion element according to an embodiment of the present invention includes a pair of electrodes; an active layer provided between the pair of electrodes and including a p-type semiconductor (P); and a buffer layer provided between one of the pair of electrodes and the active layer and including a dielectric (D). The dielectric (D) has a band gap of 4 eV or more and a relative permittivity of 20 or more. The photoelectric conversion element according to an embodiment of the present invention satisfies the following Formula (1).

$$Ec - E ( L ) > 0.8 eV \qquad ( 1 )$$

In Expression (1), Ec represents an energy level at a lower end of a conduction band of the dielectric (D), and E(L) represents a LUMO energy level of the p-type semiconductor (P).

The buffer layer is provided between one of the pair of electrodes and the active layer. Preferably, the buffer layer is provided between a first electrode and the active layer, and may function as an electron blocking layer.

In the present specification, when a reverse voltage is applied to a photoelectric conversion element and light is radiated, an electrode through which holes flow out to an external circuit is referred to as a first electrode, and an electrode through which electrons flow out to the external circuit is referred to as a second electrode.

The first electrode is an anode when a forward voltage is applied to the photoelectric conversion element, and the second electrode is a cathode when a forward voltage is applied to the photoelectric conversion element.

The photoelectric conversion element of the present embodiment suppresses an increase in dark current value after heating and has heat resistance.

In the photoelectric conversion element of the present embodiment, the dark current value (Jd) when −5 V is applied is preferably 100 nA/cm² or less, more preferably 50 nA/cm² or less, and still more preferably 20 nA/cm² or less, but is usually 0 nA/cm² or more.

In the photoelectric conversion element of the present embodiment, when a dark current value when −5 V is applied after heating at 180° C. is Jd1 and a dark current value when −5 V is applied before heating at 180° C. is Jd0, a Jd1/Jd0 value is preferably 2 or less, more preferably 1.8 or less, and still more preferably 1.5 or less, and the smaller the Jd1/Jd0 value is, the more preferable the Jd1/Jd0 value is. However, the Jd1/Jd0 value may be, for example, 0.1 or more, and may be, for example, 0.5 or more.

The reason why the photoelectric conversion element of the present embodiment suppresses an increase in dark current value after heating and has heat resistance is considered as follows, but the present invention is not limited thereto.

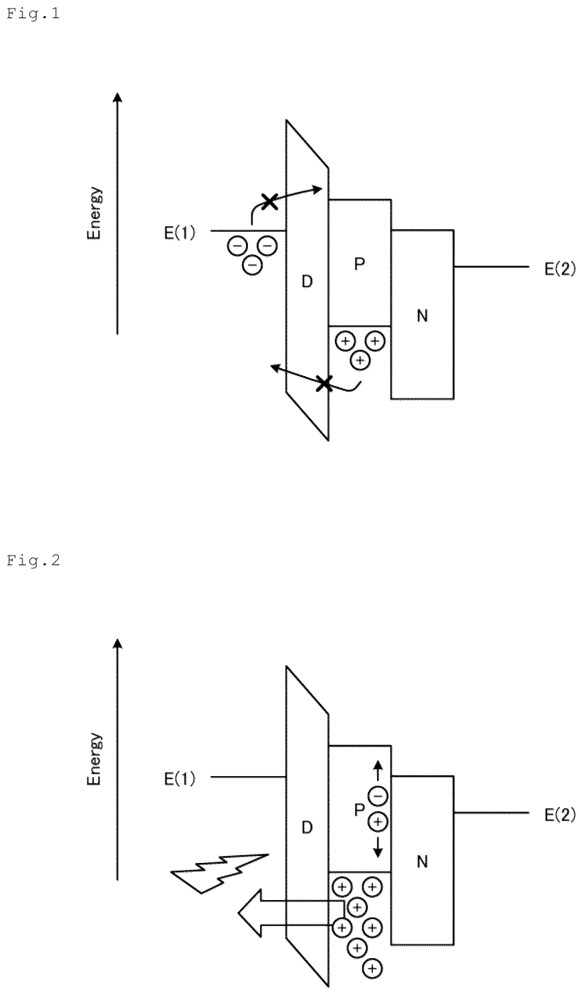

Hereinafter, the reason will be described with reference to FIGS. 1 to 3.

FIG. 1 is an energy diagram schematically illustrating an action in a case where a photoelectric conversion element according to an embodiment of the present invention is set in a dark state.

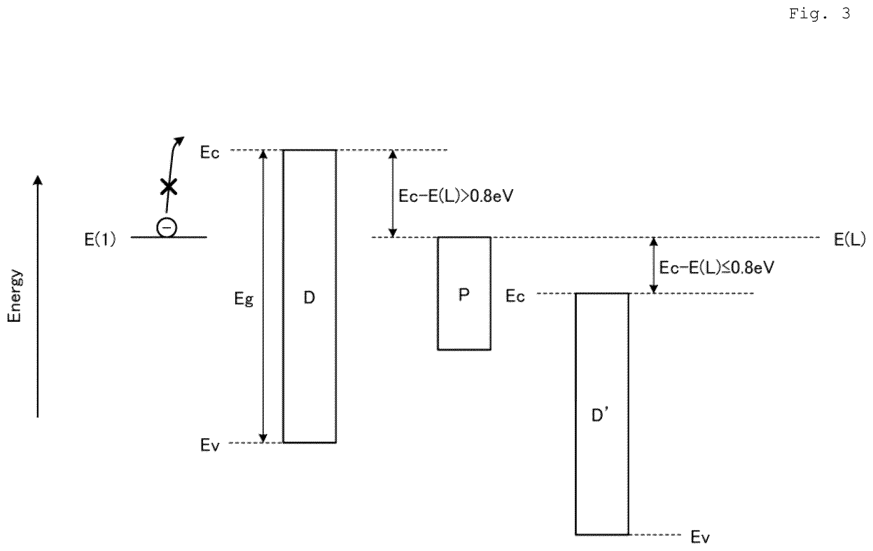

FIG. 2 is an energy diagram schematically illustrating an action in a case where a photoelectric conversion element according to an embodiment of the present invention is irradiated with light.

FIG. 3 is a diagram schematically illustrating an energy level of a constituent element of a photoelectric conversion element according to an embodiment of the present invention.

In FIGS. 1 and 2, E(1) indicates a Fermi level of the first electrode, a parallelogram D indicates an energy level of the dielectric (D), a rectangle P indicates an energy level of the p-type semiconductor (P) included in the active layer, a rectangle N indicates an energy level of the n-type semiconductor that can be included in the active layer, and E(2) indicates a Fermi level of the second electrode. The upper side of the parallelogram D indicates an energy level at the lower end of the conduction band, and the lower side of the parallelogram D indicates an energy level at the upper end of the valence band. The upper sides and the lower sides of the rectangle P and the rectangle N indicate the energy level of the LUMO and the energy level of the HOMO, respectively.

In the drawings, the energy level of the photoelectric conversion element in which the buffer layer including the dielectric (D) is directly connected to the first electrode is illustrated.

In the dark state, there are few carriers in the active layer, and the conductivity of the active layer is low. Therefore, the voltage applied to the buffer layer including the dielectric (D) is low. In such a state, since the dielectric (D) has a large band gap of 4 eV or more, as illustrated in FIG. 1, the dielectric (D) serves as a barrier when electrons are injected from the first electrode into the active layer, and also serves as a barrier when holes generated in the active layer are extracted from the first electrode. Therefore, it is considered that the photoelectric conversion element of the present embodiment can reduce the dark current value.

On the other hand, when the photoelectric conversion element is irradiated with light (bright state), there are many carriers in the active layer, and the conductivity of the active layer is high. Therefore, the voltage applied to the buffer layer including the dielectric (D) is high. In such a state, a tunneling effect occurs, and holes in the active layer are extracted to the first electrode beyond the barrier of the buffer layer. Therefore, in the photoelectric conversion element of this embodiment, excellent external quantum efficiency (EQE) is expected while the dark current value is reduced.

When the photoelectric conversion element is heated, the following changes are considered to occur in the dielectric included in the buffer layer.

The occurrence of intermediate levels with energy levels deeper (smaller) than the energy level Ec at the lower end of the conduction band results in a lower net barrier to electrons in the buffer layer.

As illustrated in FIG. 3, a difference (Ec−E(L)) between the energy level Ec at the lower end of the conduction band of the dielectric (D) and the energy level E(L) of the LUMO of the p-type semiconductor (P) included in the active layer is large and is more than 0.8 eV. Therefore, it is considered that even when an intermediate level having an energy level deeper than Ec of the dielectric (D) is generated by heating, the dielectric (D) can be a sufficient barrier against electron injection from the first electrode to the p-type semiconductor (P) in a dark state. As a result, it is considered that the dark current value of the photoelectric conversion element is maintained at the same level before and after heating. From the above, the value “Ec−E(L)” of Expression (1) is preferably more than 0.8 eV, more preferably 1.0 or more, still more preferably 1.1 or more, and further still more preferably 1.2 or more.

On the other hand, as illustrated in FIG. 3, in a combination of the dielectric (D′) and the p-type semiconductor (P) in which the difference (Ec−E(L)) between the energy level Ec at the lower end of the conduction band and the energy level E(L) of the LUMO of the p-type semiconductor (p) included in the active layer is small and 0.8 eV or less, it is considered that since the intermediate level having an energy level deeper than the energy level Ec at the lower end of the conduction band of the dielectric (D′) is generated by heating, the dielectric (D′) cannot be a sufficient barrier against electron injection from the first electrode to the p-type semiconductor (P), and the dark current value of the photoelectric conversion element increases after heating.

### 3. First Embodiment

Hereinafter, a photoelectric conversion element according to a first embodiment of the present invention will be specifically described with reference to the drawings.

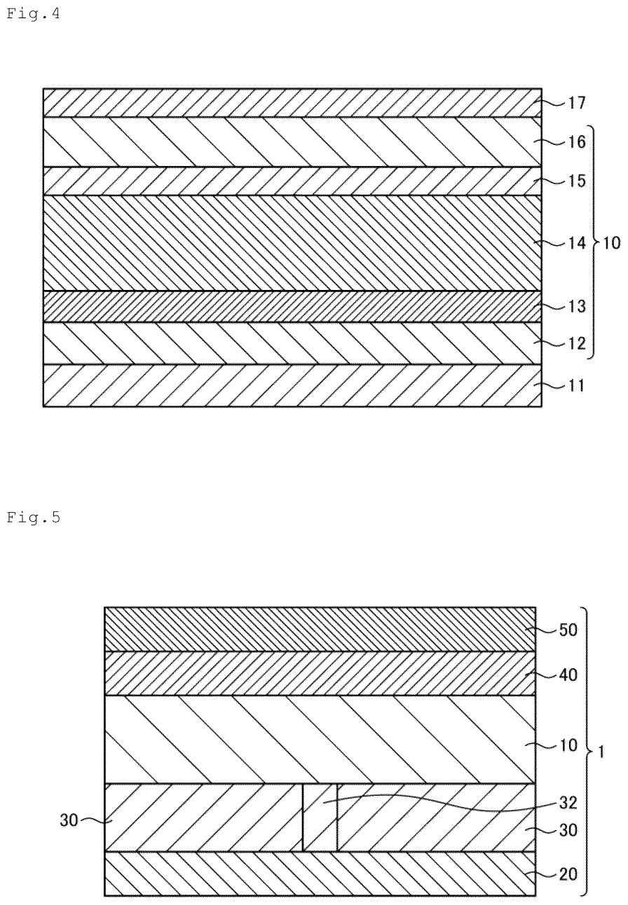

FIG. 4 is a view schematically illustrating a configuration example of the photoelectric conversion element.

As illustrated in FIG. 4, a photoelectric conversion element 10 is provided on a support substrate 11. The photoelectric conversion element 10 includes a first electrode 12 provided so as to be in contact with the support substrate 11, a buffer layer 13 as an electron blocking layer provided so as to be in contact with the first electrode 12, an active layer 14 provided so as to be in contact with the buffer layer 13, an electron transport layer 15 provided so as to be in contact with the active layer 14, and a second electrode 16 provided so as to be in contact with the electron transport layer 15. In this configuration example, a sealing member 17 is further provided so as to be in contact with the second electrode 16.

Hereinafter, constituent elements that can be included in the photoelectric conversion element of the present embodiment will be specifically described.

### 3.1. Substrate

The photoelectric conversion element is usually formed on a substrate (support substrate). In addition, there is also a case where sealing is performed by a substrate (sealing substrate). One of a pair of electrodes including a first electrode and a second electrode is usually formed on the substrate. A material of the substrate is not particularly limited as long as it is a material that is not chemically changed particularly when a layer containing an organic compound is formed.

Examples of the material of the substrate include glass, plastic, a polymer film, and silicon. In a case where an opaque substrate is used, it is preferable that an electrode provided on an opposite side to an electrode provided on the opaque substrate (in other words, the electrode provided on a side far from the opaque substrate) s a transparent or translucent electrode.

### 3.2. Electrode

The photoelectric conversion element includes a first electrode and a second electrode that are a pair of electrodes. At least one electrode of the first electrode and the second electrode is preferably a transparent or translucent electrode in order to allow light to be incident.

Examples of a material of the transparent or translucent electrode include a conductive metal oxide film and a translucent metal thin film. Specific examples of the material of the transparent or translucent electrode include indium oxide, zinc oxide, tin oxide, and a conductive material such as indium tin oxide (ITO), indium zinc oxide (IZO), or NESA, which is a composite thereof, gold, platinum, silver, and copper. As the material of the transparent or translucent electrode, ITO, IZO, or tin oxide is preferable. In addition, as the electrode, a transparent conductive film using an organic compound such as polyaniline and a derivative thereof, or polythiophene and a derivative thereof, as a material, may be used. The transparent or translucent electrode may be the first electrode or the second electrode.

When one electrode of the pair of electrodes is transparent or translucent, the other electrode may be an electrode having low light transmittance. Examples of the material of the electrode having low light transmittance include a metal and a conductive polymer. Specific examples of a material of the electrode having low light transmittance include metals such as lithium, sodium, potassium, rubidium, cesium, magnesium, calcium, strontium, barium, aluminum, scandium, vanadium, zinc, yttrium, indium, cerium, samarium, europium, terbium, and ytterbium, and an alloy of two or more of these metals, an alloy of one or more of these metals and one or more metals selected from the group consisting of gold, silver, platinum, copper, manganese, titanium, cobalt, nickel, tungsten, and tin, graphite, a graphite interlayer compound, polyaniline and a derivative thereof, and polythiophene and a derivative thereof. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

### 3.3. Buffer Layer

The buffer layer includes a dielectric (D). The buffer layer is preferably composed only of the dielectric (D). The dielectric (D) usually has a relative permittivity of 20 or more.

Since the relative permittivity of the dielectric (D) included in the buffer layer is 20 or more, holes generated in the active layer can be extracted to an external circuit when the photoelectric conversion element is irradiated with light.

The relative permittivity can be usually determined from a thickness and a capacitance of a film used for measurement by measuring the capacitance of the film of the dielectric (D) according to the method described in Document (A) “Thin Solid Films. 1977, 41, 247-259”.

In addition, the relative permittivity can be determined from the measurement results of the capacitance-voltage at 10 kHz, for example, according to the method described in Document (B) “J. App. Phys. 1985, 58, 2407”.

In addition, the relative permittivity can be determined, for example, according to the method described in Document (C) “J. App. Phys. 2000, 88, 850”.

The dielectric (D) has a band gap Eg of usually 4 eV or more, preferably 5.5 eV or more, and more preferably 6.0 eV or more, but preferably 12 eV or less, and more preferably 15 eV or less.

When the band gap Eg is equal to or more than the lower limit value, the dark current value can be maintained at a low level even after the photoelectric conversion element is heated.

The band gap Eg can be usually determined by a method combining ultraviolet photoemission spectroscopy (UPS) and inverse photoemission spectroscopy (IPS) according to the method described in Document (D) “Phys. Rev. B. 2008, 78, 085114”.

In addition, the band gap Eg can be determined, for example, according to the method described in Document (C) “J. App. Phys. 2000, 88, 850”.

The dielectric (D) is preferably an oxide including one or more selected from the group consisting of hafnium oxide, zirconium oxide, and tantalum oxide, more preferably an oxide including one or more selected from the group consisting of hafnium oxide and zirconium oxide, and still more preferably an oxide including hafnium oxide. The dielectric (D) is a multiple oxide including one or more selected from the group consisting of hafnium oxide, zirconium oxide, and tantalum oxide.

Examples of an oxide including hafnium oxide include hafnium (IV) oxide (HfO₂) (Eg: 5.7 eV (according to Document (D)), relative permittivity: 22 to 25 (according to Document (A))), and hafnium (IV) oxide is preferable.

Examples of an oxide including zirconium oxide include zirconium (IV) oxide (ZrO₂) (Eg: 5.5 eV (according to Document (D)), relative permittivity: 21 (according to Document (B))).

Examples of the oxide including tantalum oxide include tantalum (V) oxide (Ta₂O₅) (Eg: 4.0 eV, relative permittivity: 23 (each according to Document (C)).

The dielectric (D) may contain components other than hafnium oxide, zirconium oxide, and tantalum oxide. For example, the dielectric (D) may contain an aluminum atom, a silicon atom, a lanthanum atom, and/or an yttrium atom. A ratio of components other than the hafnium oxide, the zirconium oxide, and the tantalum oxide that can be contained in the dielectric (D) is preferably 50 wt % or less, more preferably 25 wt % or less, and still more preferably 10 wt % or less, but is usually 0 wt& or more and may be 0 wt %. However, a weight of the dielectric (D) is 100 wt %.

In the dielectric (D), the energy level Ec at the lower end of the conduction band satisfies Formula (1). The energy level Ec at the lower end of the conduction band of the dielectric (D) can be usually determined by a method combining the UPS method and the IPS method according to the method described in Document (D).

A thickness of the buffer layer is preferably 1 nm or more and more preferably 5 nm or more, but preferably 50 nm or less and more preferably 30 nm or less.

Since the buffer layer includes the dielectric (D), the buffer layer can have a function of blocking electrons or holes even with a thickness equal to or less than the upper limit value.

### 3.4. Active Layer

The active layer includes a p-type semiconductor (P) which is a p-type semiconductor material. The active layer preferably further includes an n-type semiconductor in addition to the p-type semiconductor (P). The active layer may include a plurality of types of p-type semiconductors (P). The active layer may include a plurality of types of n-type semiconductors. The active layer according to the present embodiment has a bulk heterojunction type structure.

Whether the semiconductor included in the active layer functions as either a p-type semiconductor or an n-type semiconductor may be determined relatively from a HOMO energy level value or a LUMO energy level value of the selected compound.

A relationship between an energy level value of each of a HOMO and a LUMO of the p-type semiconductor (P) and an energy level value of each of a HOMO and a LUMO of the n-type semiconductor can be appropriately set within a range in which the active layer exhibits a predetermined function such as a photoelectric conversion function or a photodetection function.

(1) p-Type Semiconductor (P)

In the p-type semiconductor (P) included in the active layer according to the present embodiment, the LUMO energy level satisfies Formula (1).

The LUMO energy level of the p-type semiconductor (P) can be determined using, for example, the UPS method according to the method described in Examples.

In the present embodiment, the p-type semiconductor (P) may be a low-molecular-weight compound or a high-molecular-weight compound.

Examples of the p-type semiconductor (P) that is a low-molecular-weight compound include phthalocyanine, metal phthalocyanine, porphyrin, metal porphyrin, oligothiophene, tetracene, pentacene, and rubrene.

The p-type semiconductor (P) according to the present embodiment is preferably a π-conjugated polymer compound. The p-type semiconductor (P) according to the present embodiment is more preferably a π-conjugated polymer compound having a donor/acceptor structure containing a donor structural unit and an acceptor structural unit.

In the present embodiment, the structural unit capable of constituting the p-type semiconductor (P) includes a structural unit in which a donor structural unit and an acceptor structural unit are directly bonded, and further includes a structural unit in which a donor structural unit and an acceptor structural unit are bonded via an arbitrary suitable spacer (group or structural unit).

Examples of the p-type semiconductor (P) that is a polymer compound include polyvinylcarbazole and a derivative thereof, polysilane and a derivative thereof, a polysiloxane derivative having an aromatic amine structure in a side chain or a main chain, polyaniline and a derivative thereof, polythiophene and a derivative thereof, polypyrrole and a derivative thereof, polyphenylene vinylene and a derivative thereof, polythienylene vinylene and a derivative thereof, and polyfluorene and a derivative thereof.

From the viewpoint of reducing the dark current, it is preferable that the p-type semiconductor (P) is a polymer compound containing a structural unit represented by the following Formula (I) and/or a structural unit represented by the following Formula (II).

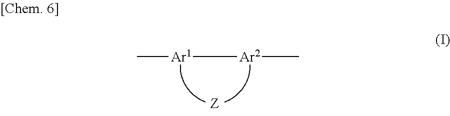

In Formula (I), Ar¹ and Ar² each independently represent a trivalent aromatic heterocyclic group which may have a substituent, and Z represents a group represented by any one of the following Formulas (Z-1) to (Z-7).

[Chem. 7]

—Ar³— (II)

In Formula (II), Ar³ represents a divalent aromatic heterocyclic group.

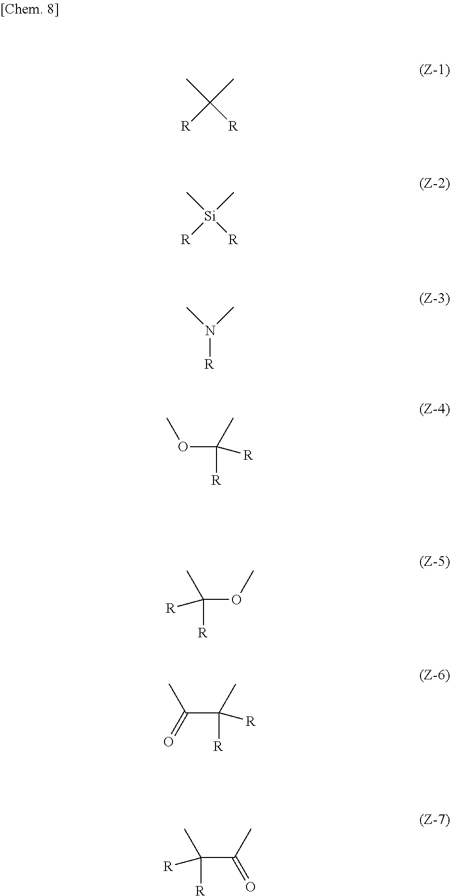

In Formulas (Z-1) to (Z-7), R represents
a hydrogen atom,
a halogen atom,
an alkyl group which may have a substituent,
a cycloalkyl group which may have a substituent,
an alkenyl group which may have a substituent,
a cycloalkenyl group which may have a substituent,
an alkynyl group which may have a substituent,
a cycloalkynyl group which may have a substituent,
an aryl group which may have a substituent,
an alkyloxy group which may have a substituent,
a cycloalkyloxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an imine residue which may have a substituent,
an amide group which may have a substituent,
an acid imide group which may have a substituent,
a substituted oxycarbonyl group which may have a substituent,
a cyano group,
a nitro group,
a group represented by —C(═O)—R^{c}, or
a group represented by —SO₂—R^{d}, and
R^{c} and R^{d} each independently represent
a hydrogen atom,
an alkyl group which may have a substituent,
a cycloalkyl group which may have a substituent,
an aryl group which may have a substituent,
an alkyloxy group which may have a substituent,
a cycloalkyloxy group which may have a substituent,
an aryloxy group which may have a substituent, or
a monovalent heterocyclic group which may have a substituent.

In Formulas (Z-1) to (Z-7), when the number of R's is two, the two R's may be the same as or different from each other. Preferably, two R's are the same as each other.

R in Formulas (Z-1) to (Z-7) is preferably a hydrogen atom, an alkyl group, or an aryl group, more preferably a hydrogen atom or an alkyl group, still more preferably a hydrogen atom or an alkyl group having 1 to 40 carbon atoms, further still more preferably a hydrogen atom or an alkyl group having 1 to 30 carbon atoms, and particularly preferably a hydrogen atom or an alkyl group having 1 to 20 carbon atoms. These groups may have a substituent. In a case where a plurality of substituents are present, the plurality of substituents may be the same as or different from each other.

Z is preferably a group represented by Formula (Z-4) or Formula (Z-5).

The structural unit represented by Formula (I) is preferably a structural unit represented by the following Formula (I-1).

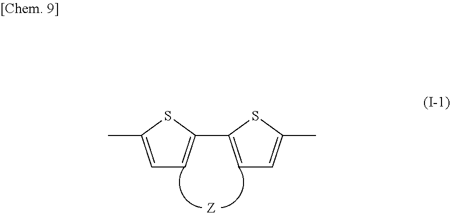

In Formula (I-1), Z has the same meaning as described above.

Examples of the structural unit represented by Formula (I-1) include structural units represented by the following Formulas (501) to (505). The structural unit represented by Formula (I) is more preferably a structural unit represented by Formula (501).

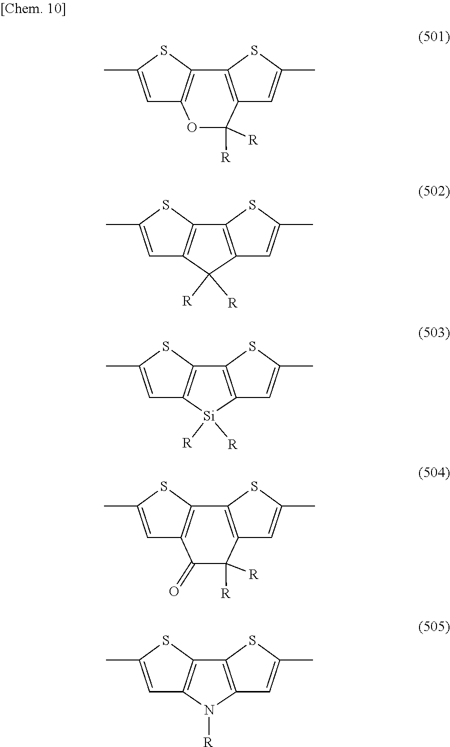

In Formulas (501) to (505), R has the same meaning as described above. In a case where two R's are present, the two R's may be the same as or different from each other. Preferably, in Formulas (501) to (505), two R's are the same as each other.

R in Formulas (501) to (505) is preferably a hydrogen atom, an alkyl group, or an aryl group, more preferably a hydrogen atom or an alkyl group, still more preferably a hydrogen atom or an alkyl group having 1 to 40 carbon atoms, further still more preferably a hydrogen atom or an alkyl group having 1 to 30 carbon atoms, and particularly preferably a hydrogen atom or an alkyl group having 1 to 20 carbon atoms. These groups may have a substituent. In a case where a plurality of substituents are present, the plurality of substituents may be the same as or different from each other.

In Formula (II), the number of carbon atoms of the divalent aromatic heterocyclic group represented by Ar³ is usually 2 to 60, preferably 4 to 60, and more preferably 4 to 20. The divalent aromatic heterocyclic group represented by Ar³ may have a substituent. Examples of the substituent which may be included in the divalent aromatic heterocyclic group represented by Ar³ include a halogen atom, an alkyl group, an aryl group, an alkoxy group, an aryloxy group, an alkylthio group, an arylthio group, a monovalent heterocyclic group, a substituted amino group, an acyl group, an imine residue, an amide group, an acid imide group, a substituted oxycarbonyl group, an alkenyl group, an alkynyl group, a cyano group, and a nitro group.

Examples of the divalent aromatic heterocyclic group represented by Ar³ include groups represented by the following Formulas (101) to (190) and groups in which these groups are substituted with substituents.

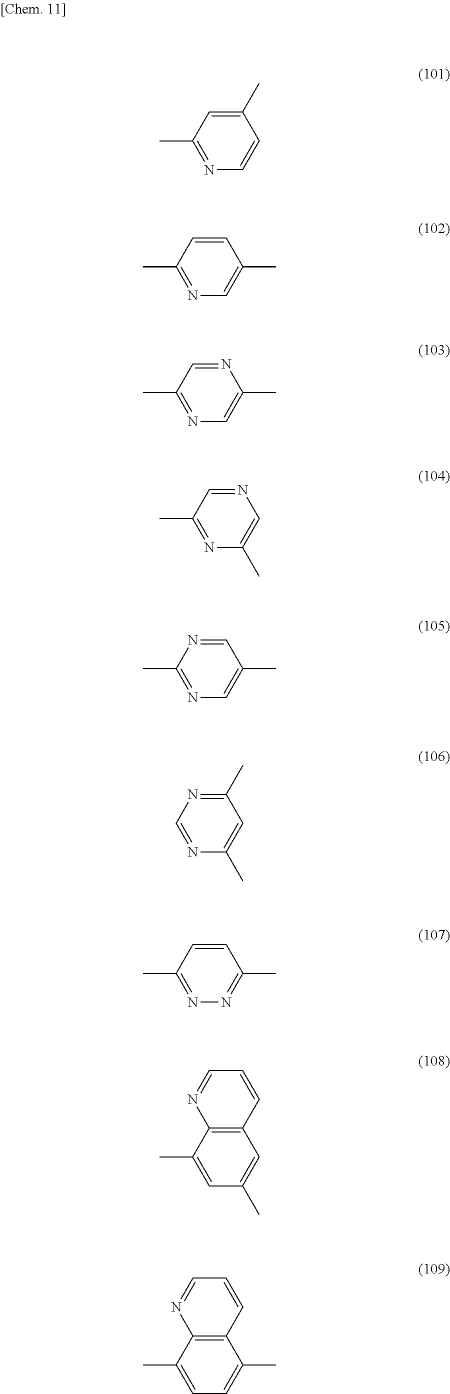

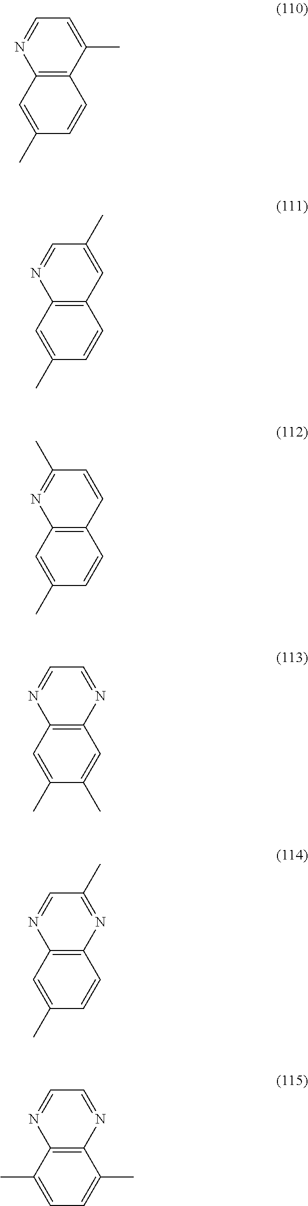

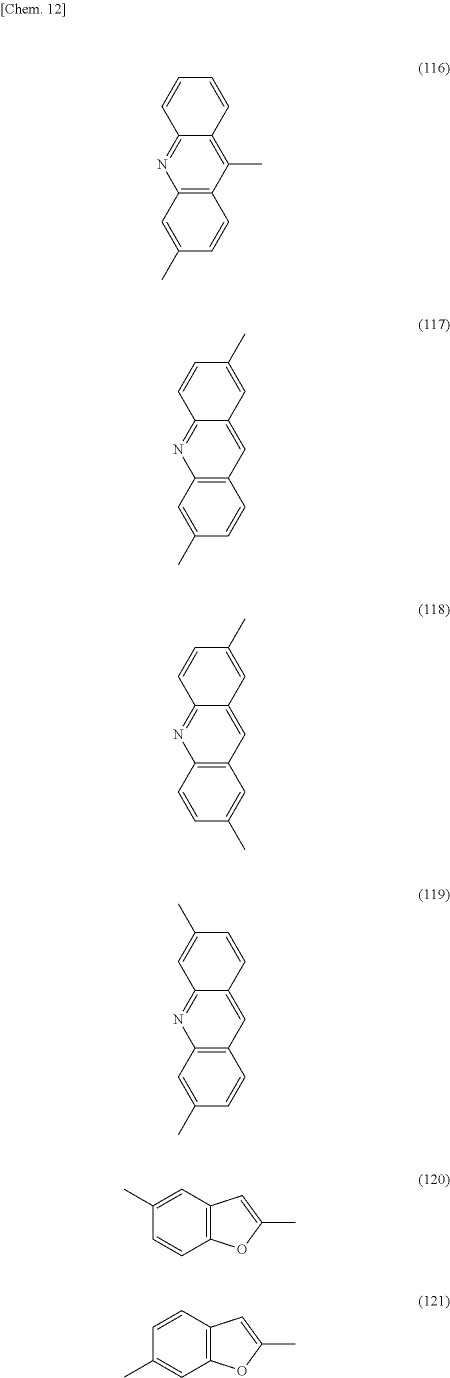

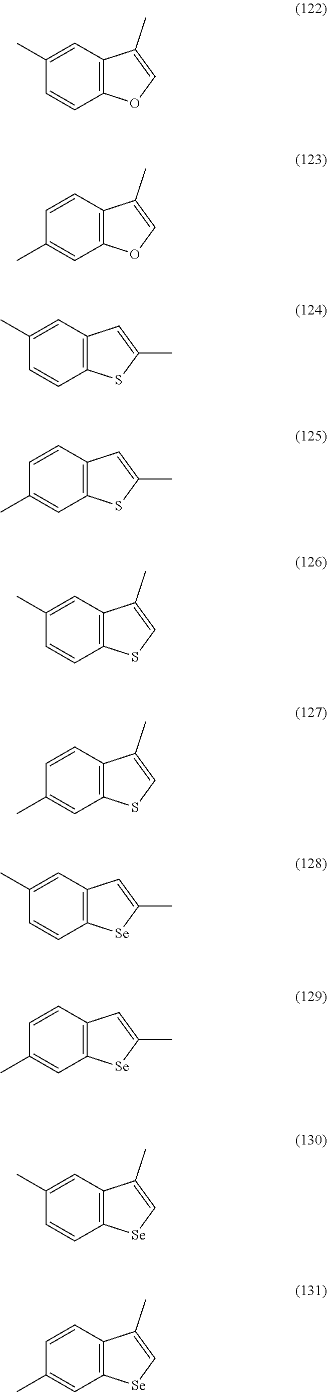

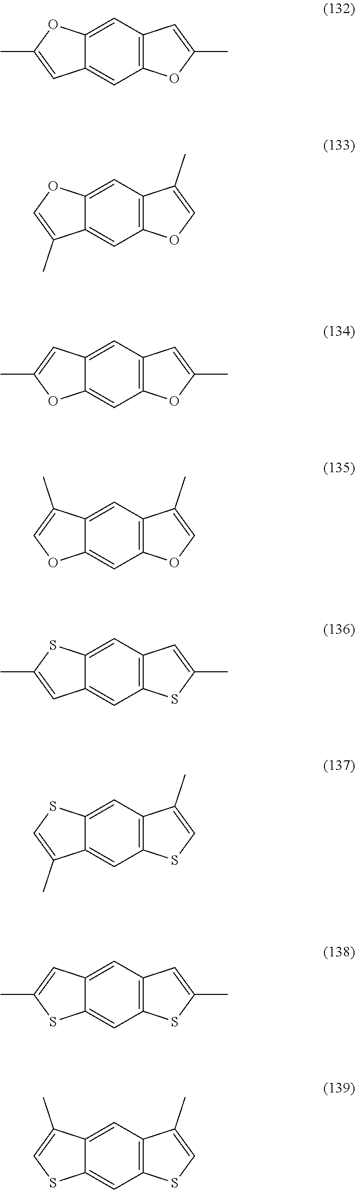

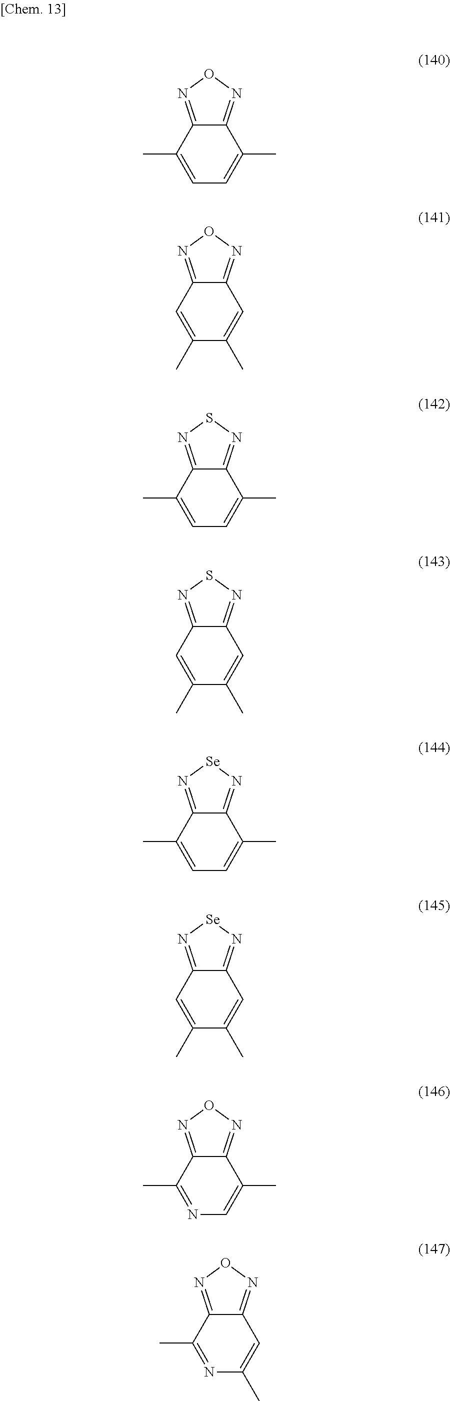

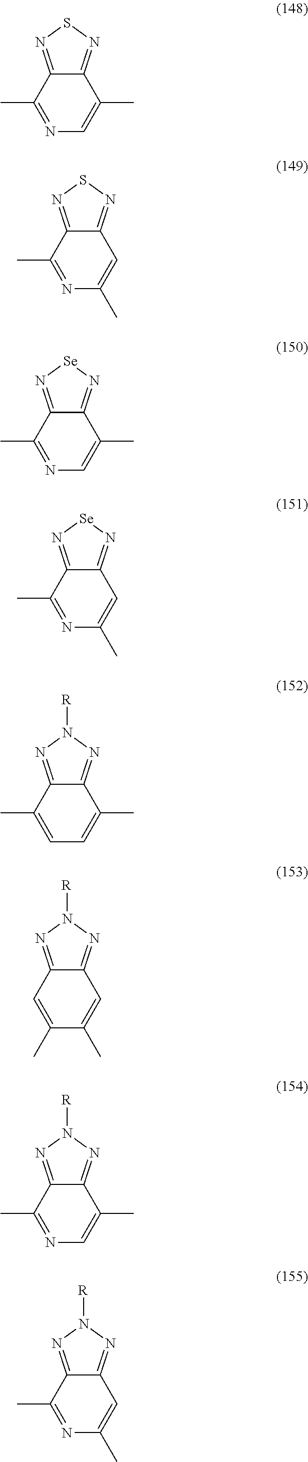

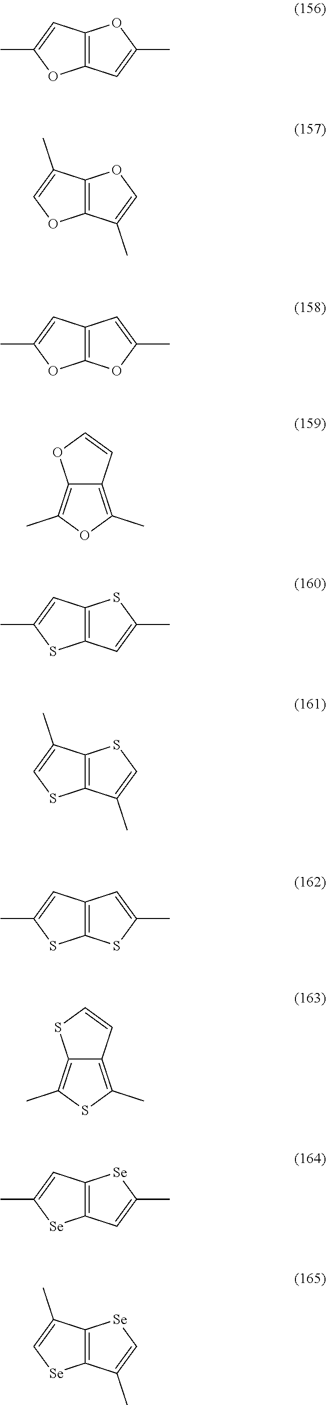

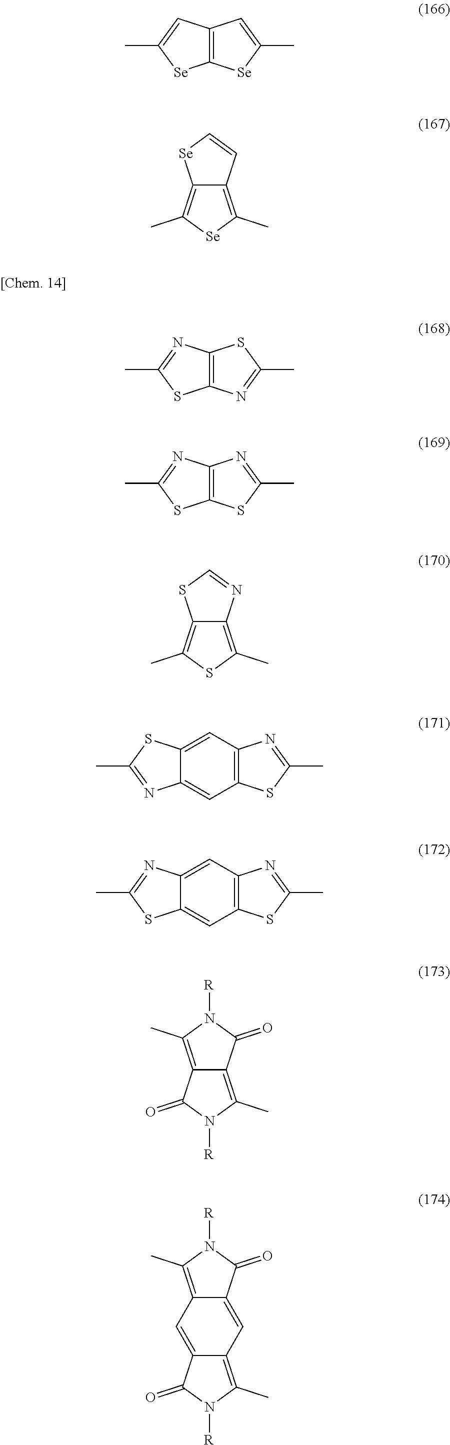

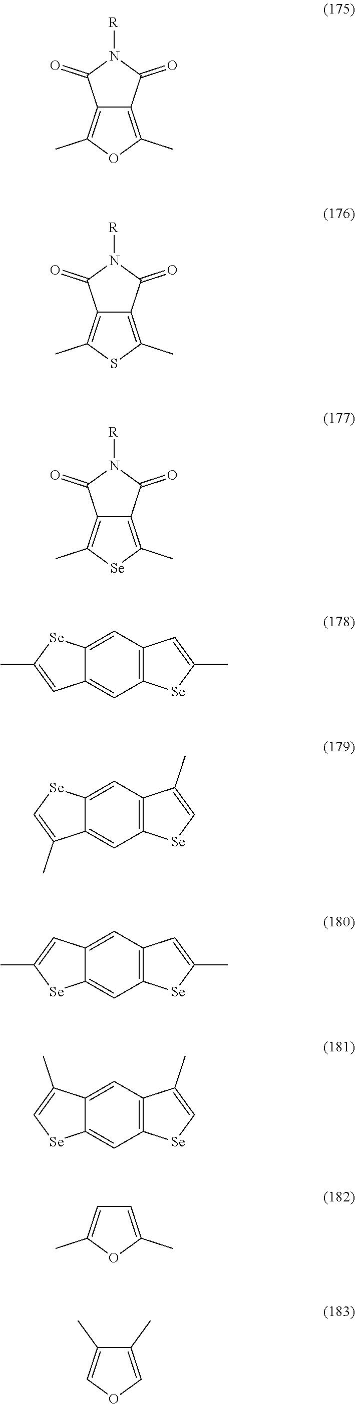

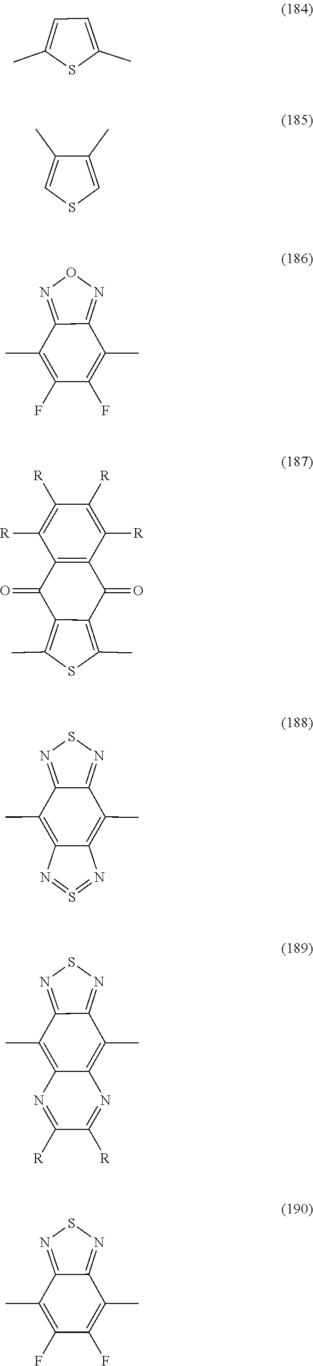

In Formulas (101) to (190), R has the same meaning as described above. In a case where a plurality of R's are present, the plurality of R's may be the same as or different from each other.

The structural unit represented by Formula (II) is preferably a structural unit represented by the following Formulas (II-1) to (II-7), and more preferably a structural unit represented by the following Formula (II-6) or (II-7).

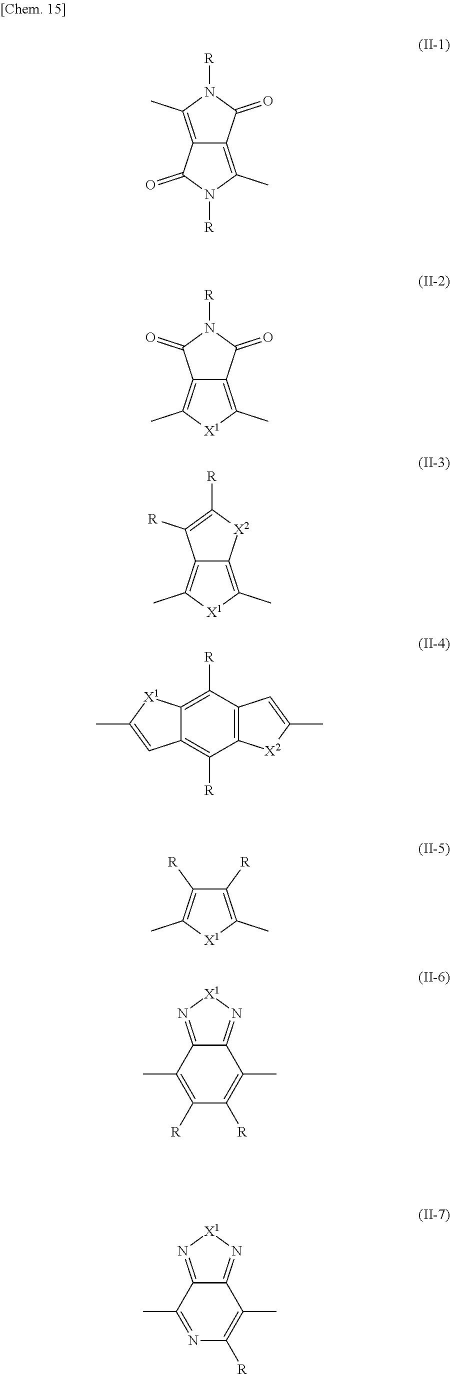

In Formulas (II-1) to (II-7), X¹ and X² each independently represent an oxygen atom or a sulfur atom, and R has the same meaning as described above. In a case where a plurality of R's are present, the plurality of R's may be the same as or different from each other. In Formulas (II-1) to (II-7), R is preferably a hydrogen atom or a halogen atom, and more preferably a hydrogen atom or a fluorine atom. In Formulas (II-1) to (II-7), when a plurality of R's are present, it is more preferable that R's are a hydrogen atom or a halogen atom at the same time, and still more preferably that R's are a hydrogen atom or a fluorine atom at the same time.

Both X¹ and X² in Formulas (II-1) to (II-7) are preferably sulfur atoms from the viewpoint of availability of a raw material compound.

The polymer compound that is a p-type semiconductor (P) may contain two or more structural units of Formula (I) or two or more structural units of Formula (II).

The polymer compound that is a p-type semiconductor (P) may contain a structural unit represented by the following Formula (III) from the viewpoint of improving solubility in the solvent.

[Chem. 16]

—Ar⁴— (III)

In Formula (III), Ar⁴ represents an arylene group.

The arylene group represented by Ar⁴ means a remaining atomic group obtained by removing two hydrogen atoms from an aromatic hydrocarbon which may have a substituent.

Examples of the substituent which may be included in the aromatic hydrocarbon include the same substituents as the substituent that the divalent aromatic heterocyclic group represented by Ar³ may have.

In the arylene group, the number of carbon atoms in a moiety excluding the substituent is usually 6 to 60 and preferably 6 to 20. The number of carbon atoms in the arylene group having the substituent is usually 6 to 100.

Examples of the arylene group include phenylene groups (for example, the following Formulas 1 to 3), naphthalene-diyl groups (for example, the following Formulas 4 to 13), anthracene-diyl groups (for example, the following Formulas 14 to 19), biphenyl-diyl groups (for example, the following Formulas 20 to 25), terphenyl-diyl groups (for example, the following Formulas 26 to 28), fused ring compound groups (for example, the following Formulas 29 to 35), fluorene-diyl groups (for example, the following Formulas 36 to 38), and benzofluorene-diyl groups (for example, the following Formulas 39 to 46).

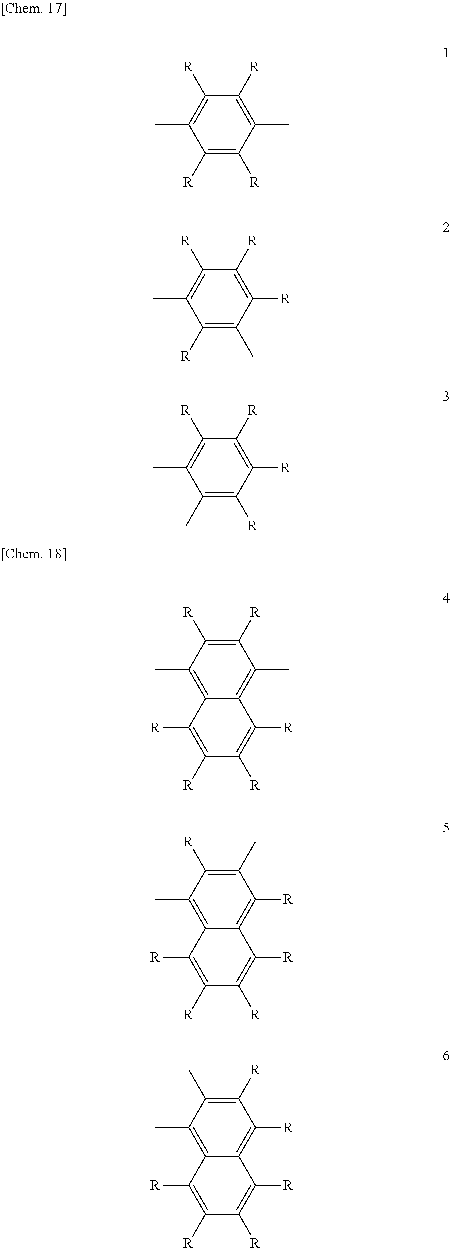

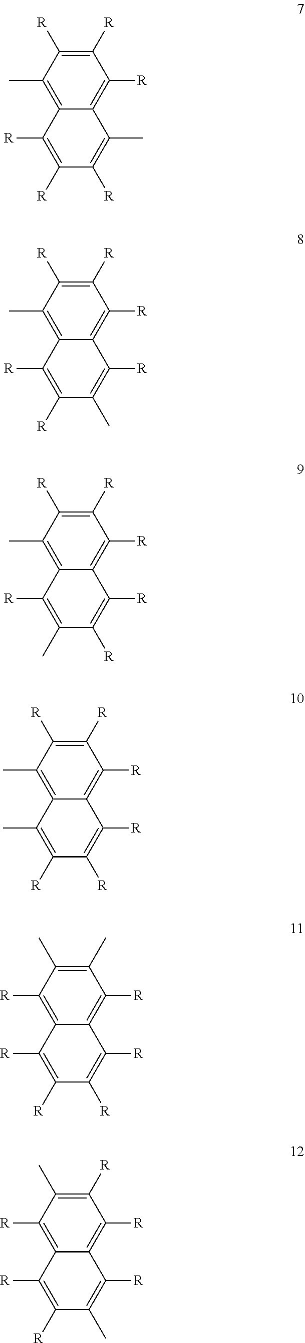

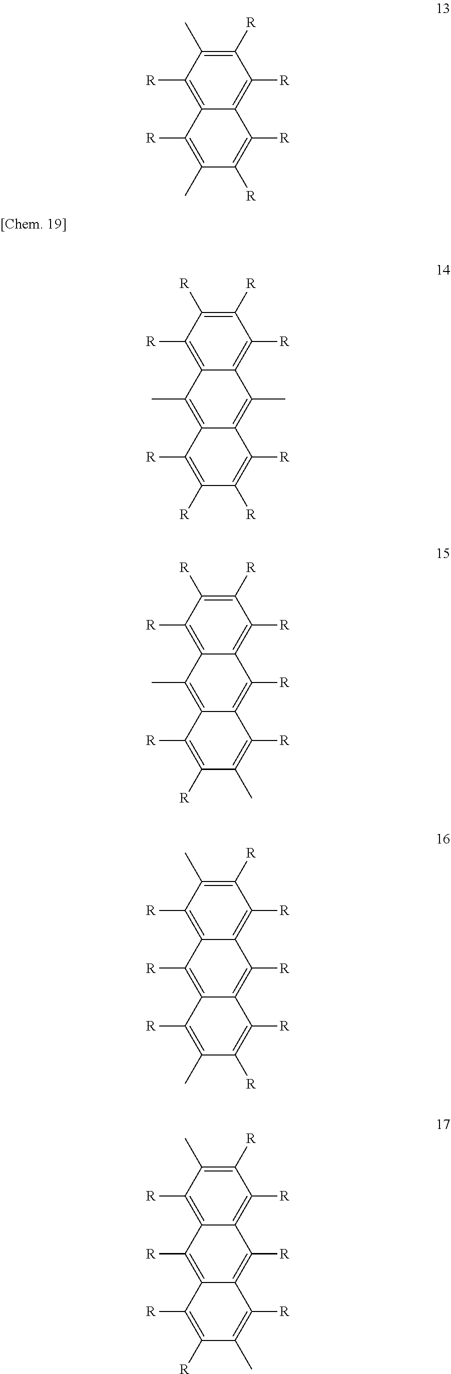

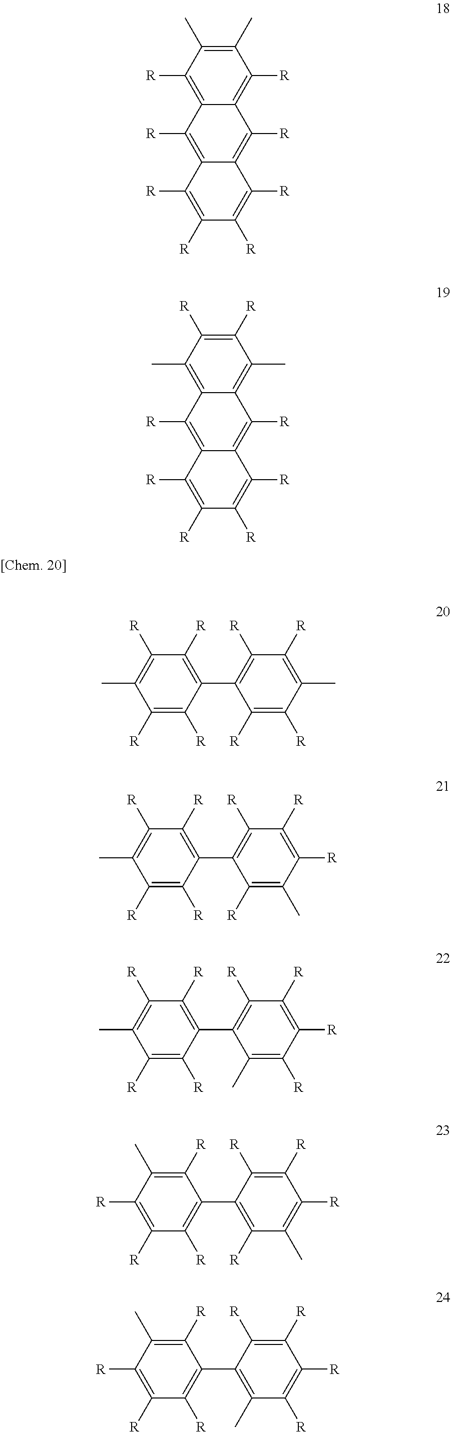

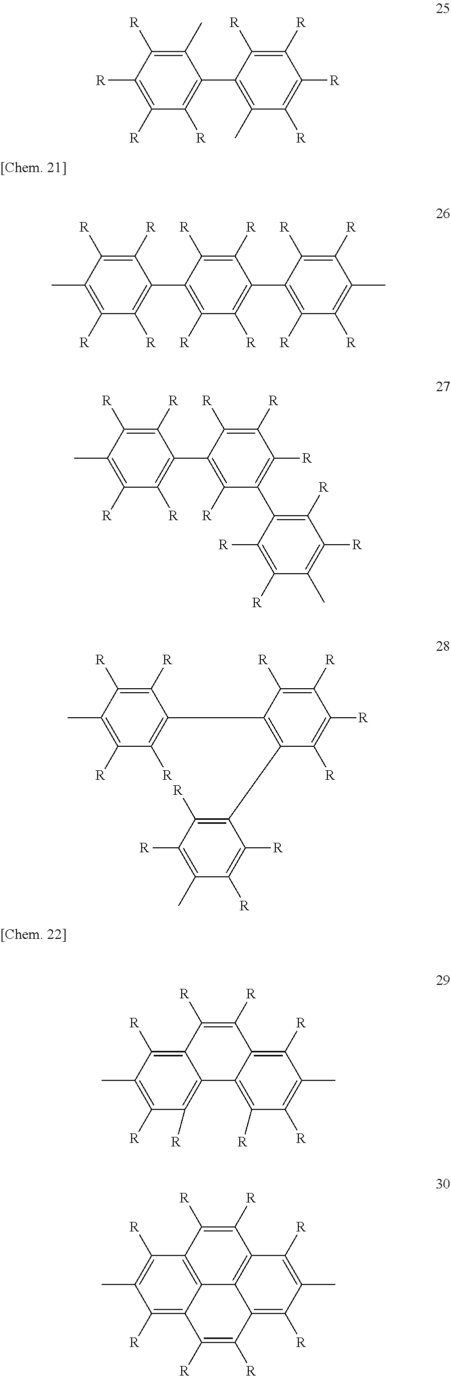

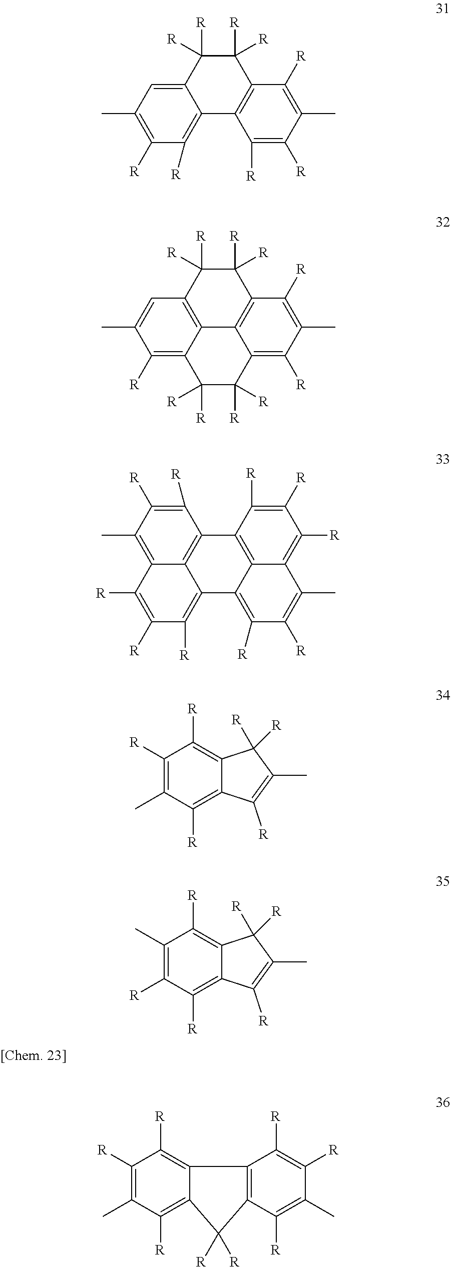

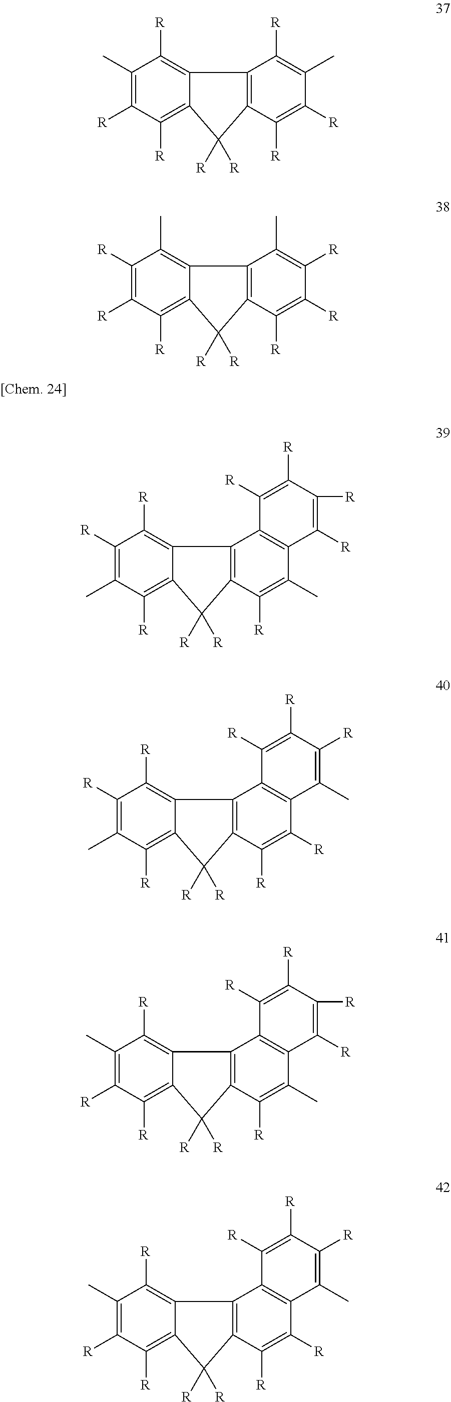

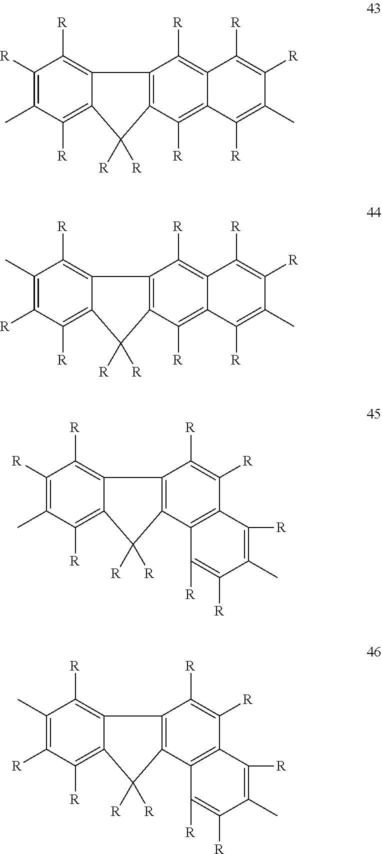

In Formulas 1 to 46, R has the same meaning as described above. In a case where the number of R's is plural, the plurality of R's may be the same as or different from each other.

In a case where the polymer compound as a p-type semiconductor (P) contains a structural unit represented by Formula (I) and/or a structural unit represented by Formula (II), when the amount of all the structural units contained in the polymer compound is 100 mol %, the total amount of the structural unit represented by Formula (I) and/or the structural unit represented by Formula (II) is usually 20 to 100 mol %, and preferably 40 to 100 mol % and still more preferably 50 to 100 mol % because charge transportability as the p-type semiconductor is improved.

Preferred specific examples of the polymer compound that is a p-type semiconductor (P) include polymer compounds represented by the following Formulas P-1 and P-2.

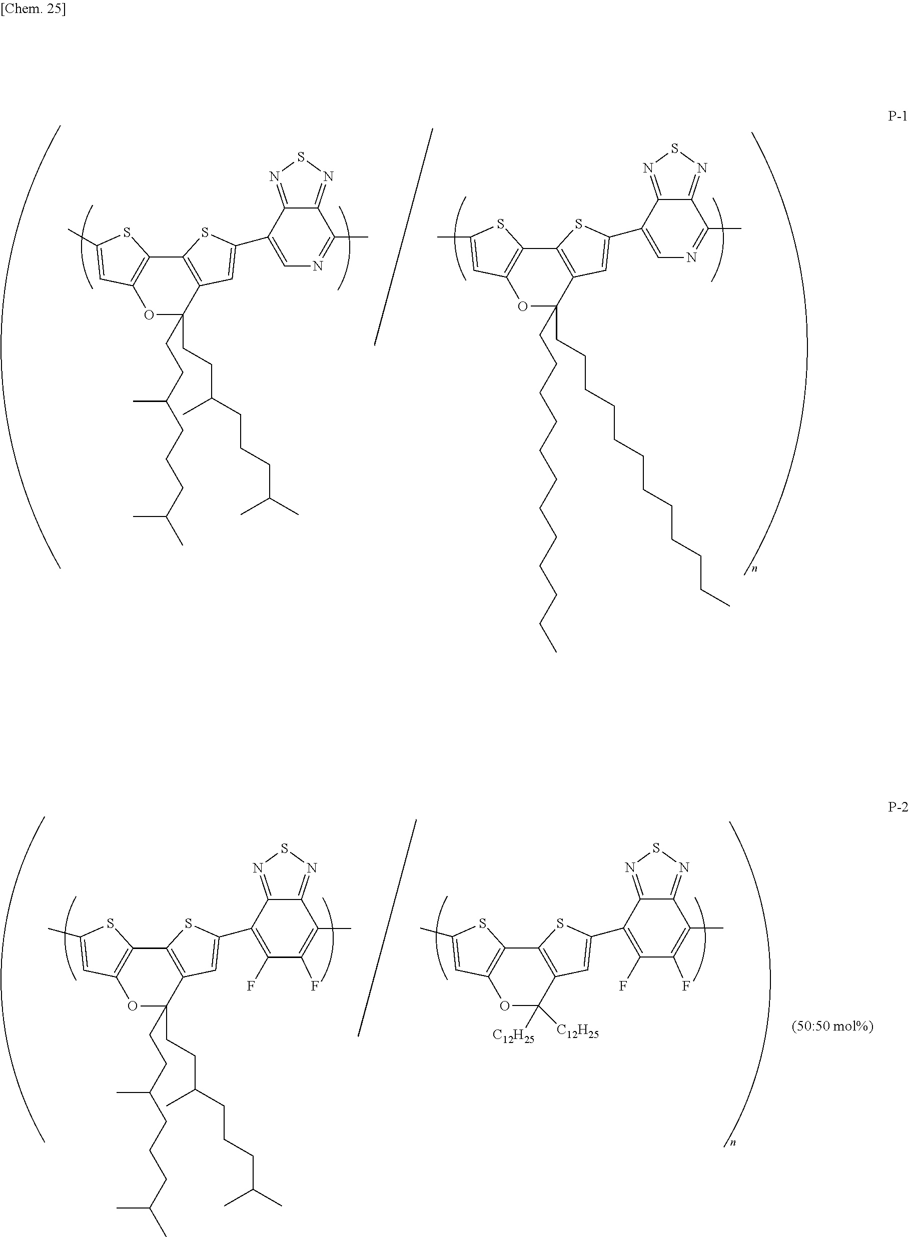

A weight average molecular weight in terms of polystyrene of the polymer compound as a p-type semiconductor (P) is usually 1×10³ to 1×10⁸, and is preferably 1×10³ to 1×10⁶ from the viewpoint of improving solubility in the solvent.

The active layer according to the present embodiment may contain only one polymer compound as a p-type semiconductor (P), or may contain two or more polymer compounds in any combination.

(2) n-Type Semiconductor

The n-type semiconductor that can be included in the active layer of the present embodiment may be a low-molecular-weight compound or a polymer compound.

Examples of the n-type semiconductor (electron-accepting compound) that is a low-molecular-weight compound include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, a diphenyldicyanoethylene and a derivative thereof, a diphenoquinone derivative, a metal complex of 8-hydroxyquinoline and a derivative thereof, fullerene such as C₆₀ fullerene and a fullerene derivative that is a derivative thereof (hereinafter, may be referred to as a fullerene compound), and a phenanthrene derivative such as bathocuproine.

Examples of the n-type semiconductor that is a polymer compound include polyvinylcarbazole and a derivative thereof, polysilane and a derivative thereof, a polysiloxane derivative having an aromatic amine structure in a side chain or a main chain, polyaniline and a derivative thereof, polythiophene and a derivative thereof, polypyrrole and a derivative thereof, polyphenylene vinylene and a derivative thereof, polythienylene vinylene and a derivative thereof, polyquinoline and a derivative thereof, polyquinoxaline and a derivative thereof, and polyfluorene and a derivative thereof.

In an embodiment, the n-type semiconductor included in the active layer is preferably one or more selected from fullerene and a fullerene derivative, and more preferably a fullerene derivative.

Examples of the fullerene include C₆₀ fullerene, C₇₀ fullerene, C₇₆ fullerene, C₇₈ fullerene, and C₈₄ fullerene. Examples of the fullerene derivative include derivatives of these fullerenes. The fullerene derivative means a compound in which at least a part of fullerene is modified.

Examples of the fullerene derivative include compounds represented by the following Formulas.

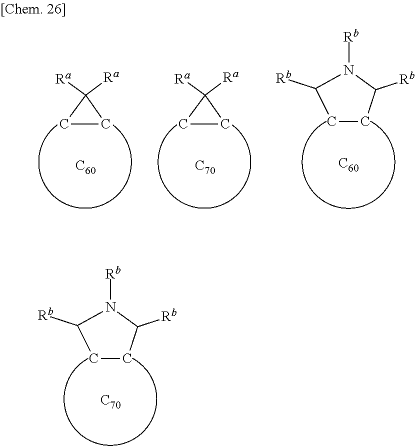

In the formula,

R^{a} represents an alkyl group which may have a substituent, an aryl group which may have a substituent, a monovalent heterocyclic group which may have a substituent, or a group having an ester structure. The plurality of R^{a}'s may be the same as or different from each other.

R^{b} represents an alkyl group which may have a substituent or an aryl group which may have a substituent. The plurality of R^{b}'s may be the same as or different from each other.

Examples of the group represented by R^{a} and having an ester structure include groups represented by the following formulas.

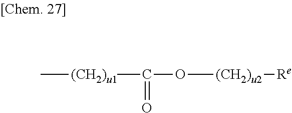

In the formula, u1 represents an integer of 1 to 6. u2 represents an integer of 0 to 6. R^{e} represents an alkyl group which may have a substituent, an aryl group which may have a substituent, or a monovalent heterocyclic group which may have a substituent.

Examples of the C₆₀ fullerene derivative include the following compounds.

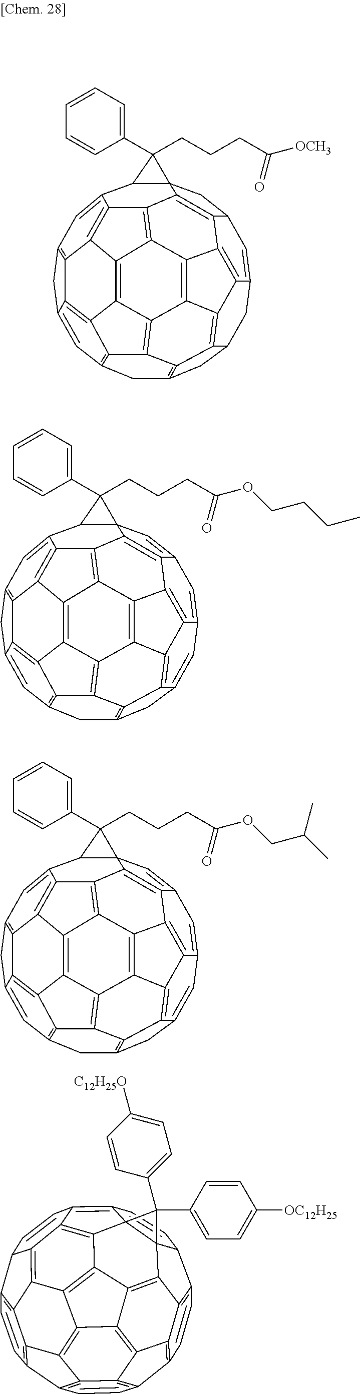

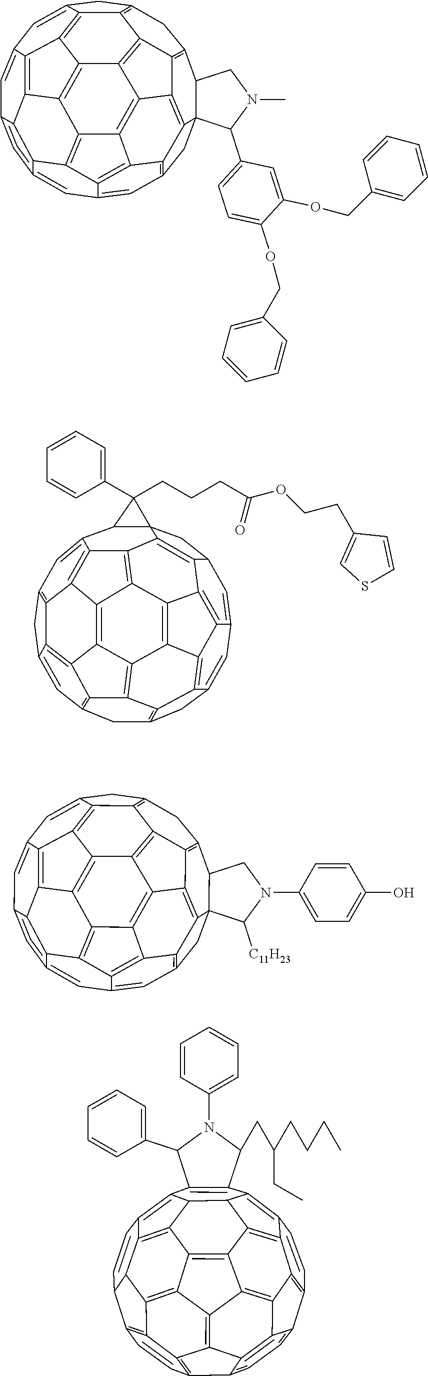

Examples of the C fullerene derivative include the following compounds.

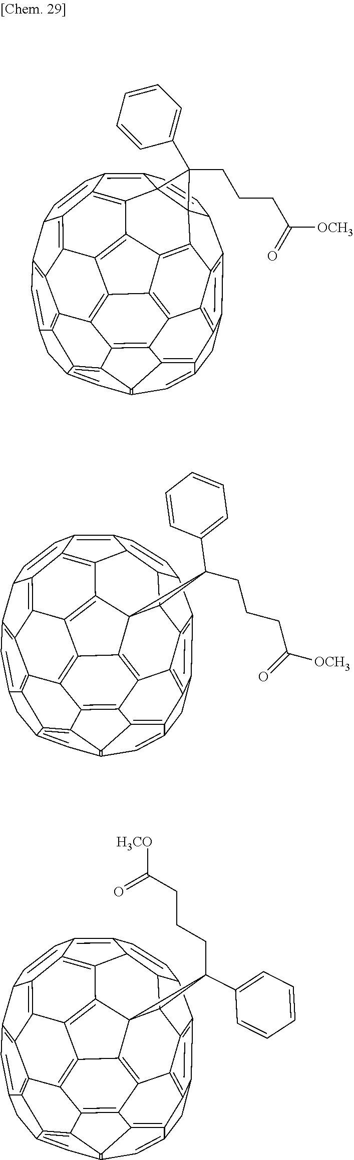

Specific examples of the fullerene derivative include [6,6]-phenyl-C61 butyric acid methyl ester (C60PCBM), [6,6]-phenyl-C71 butyric acid methyl ester (C70PCBM), [6,6]-phenyl-C85 butyric acid methyl ester (C84PCBM), and [6,6]-thienyl-C61 butyric acid methyl ester.

As the n-type semiconductor, a compound that is not a fullerene compound can be used. In the present specification, the n-type semiconductor that is not a fullerene compound is referred to as a “non-fullerene compound”. As the non-fullerene compound, various compounds are known, and any suitable conventionally known non-fullerene compound can be used as the n-type semiconductor in the present embodiment.

The active layer according to the present embodiment may contain one or a plurality of compounds as the n-type semiconductor.

In an embodiment, the non-fullerene compound that is an n-type semiconductor is preferably a compound having a perylene tetracarboxylic acid diimide structure. Examples of the compound that is a non-fullerene compound and has a perylene tetracarboxylic acid diimide structure include compounds represented by the following formulas.

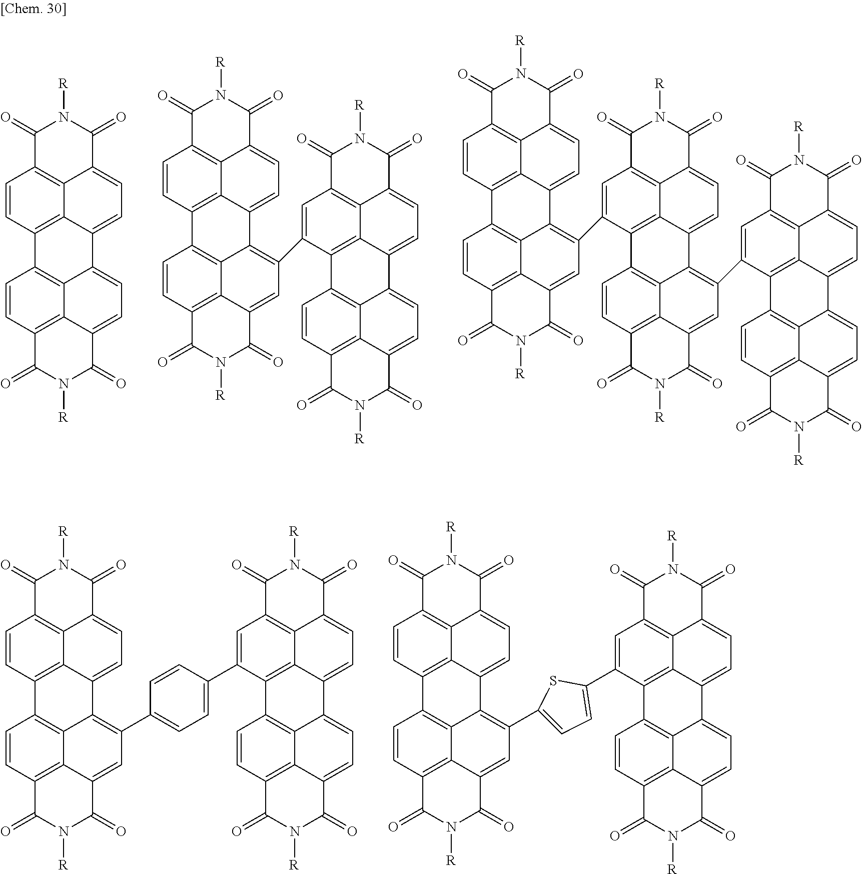

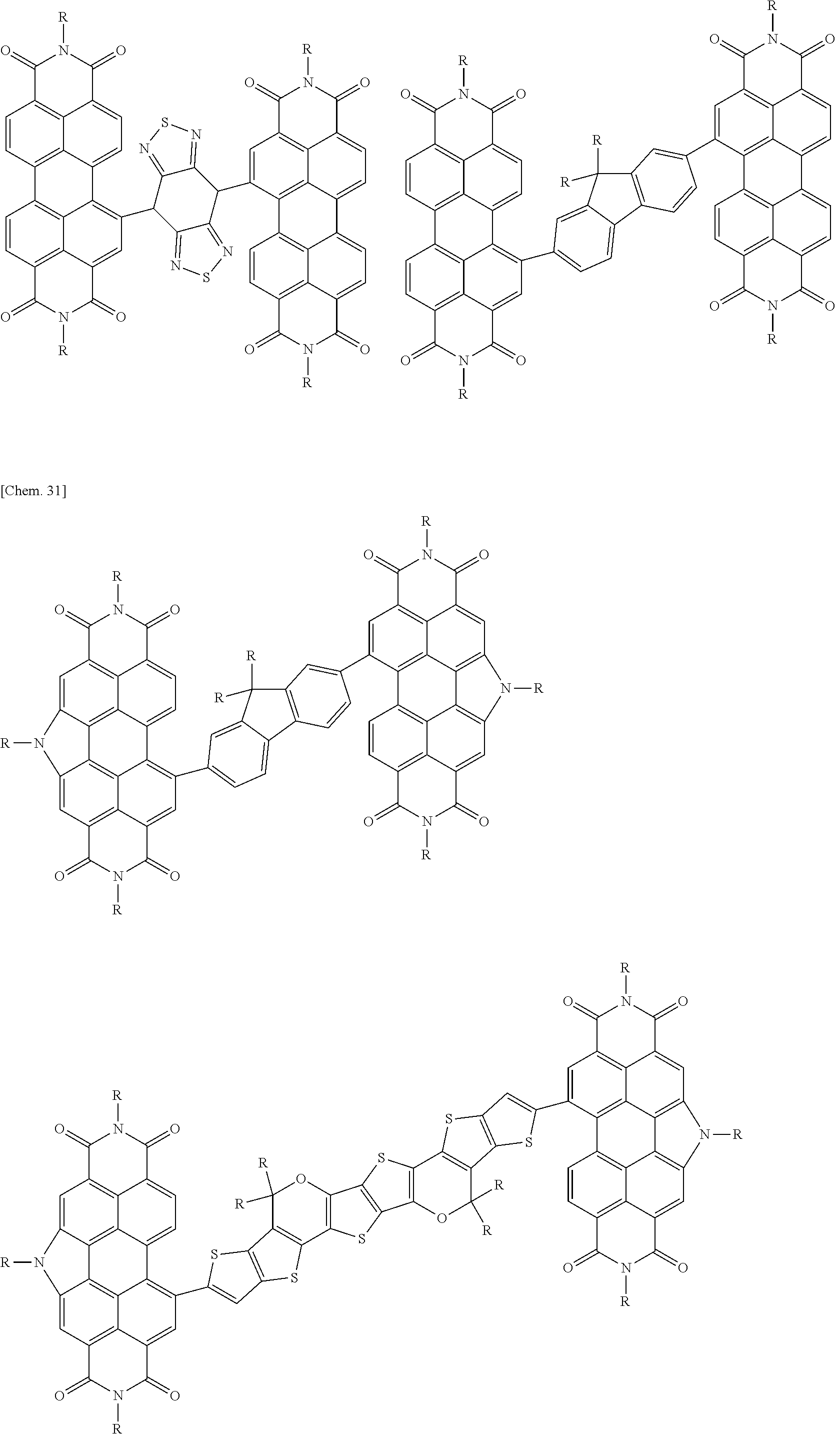

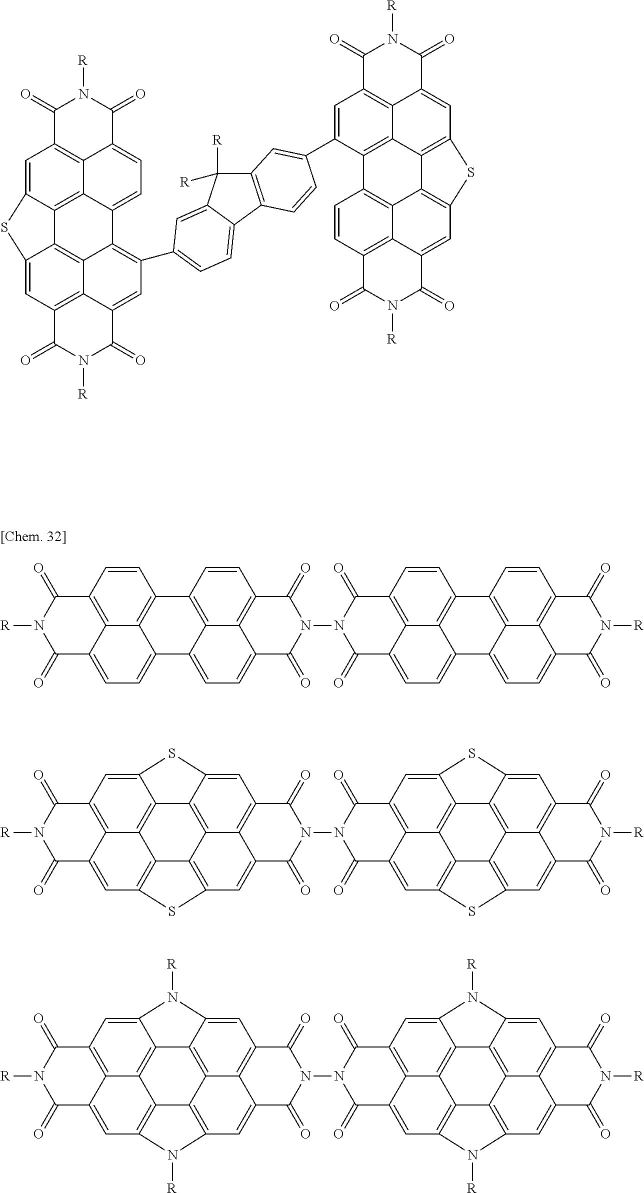

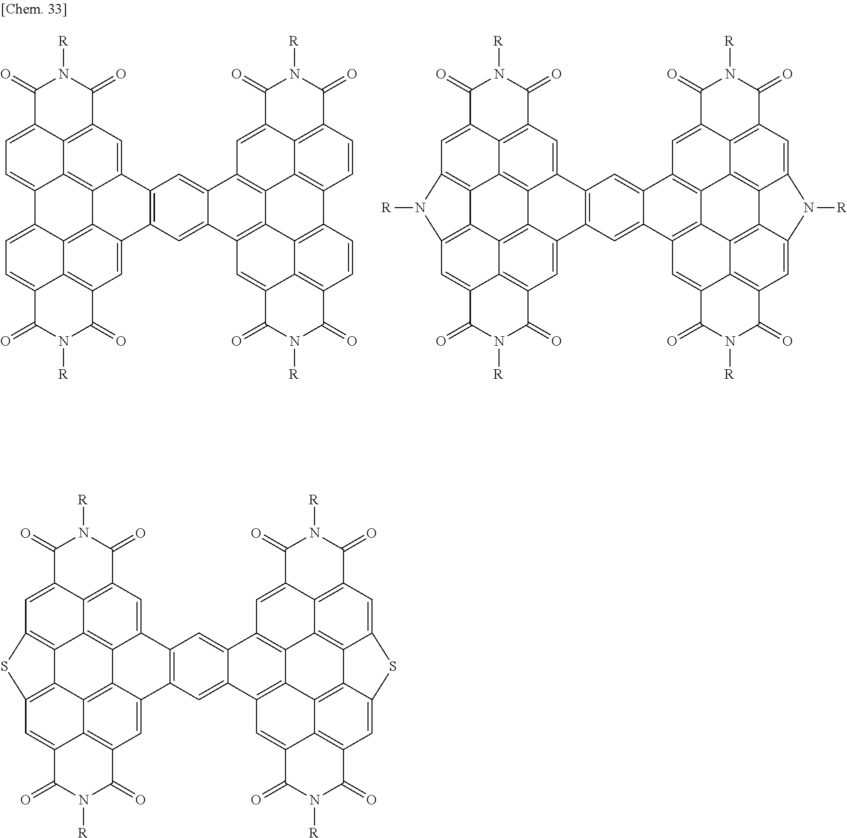

In the formulas, R is as defined above. The plurality of R's may be the same as or different from each other.

In an embodiment, the n-type semiconductor material preferably contains a compound represented by the following Formula (V). The compound represented by the following Formula (V) is a non-fullerene compound having a perylene tetracarboxylic acid diimide structure.

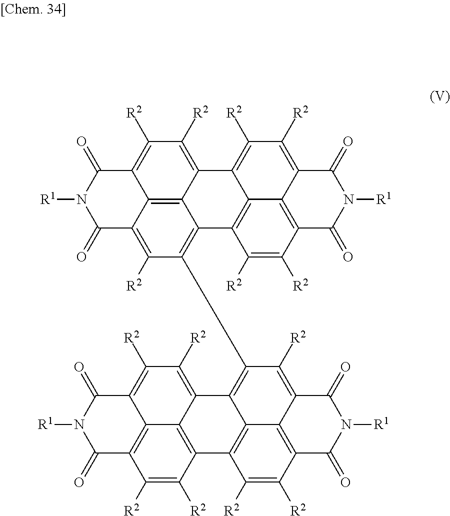

In Formula (V), R¹ represents a hydrogen atom, a halogen atom, an alkyl group which may have a substituent, a cycloalkyl group which may have a substituent, an alkyloxy group which may have a substituent, a cycloalkyloxy group which may have a substituent, an aryl group which may have a substituent, or a monovalent aromatic heterocyclic group which may have a substituent. The plurality of R¹'s may be the same as or different from each other.

Preferably, the plurality of R¹'s are each independently an alkyl group which may have a substituent.

R² represents a hydrogen atom, a halogen atom, an alkyl group which may have a substituent, a cycloalkyl group which may have a substituent, an alkyloxy group which may have a substituent, a cycloalkyloxy group which may have a substituent, an aryl group which may have a substituent, or a monovalent aromatic heterocyclic group which may have a substituent. The plurality of R²'s may be the same as or different from each other.

Preferred examples of the compound represented by Formula (V) include a compound represented by the following formula.

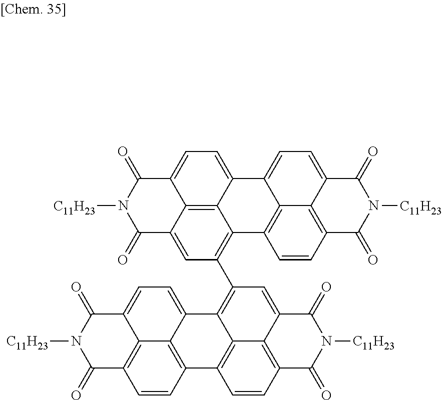

In an embodiment, the n-type semiconductor material preferably contains a compound represented by the following Formula (VI).

A¹-B¹⁰-A² (VI)

In the Formula (VI),

A¹ and A² each independently represent an electron-withdrawing group, and B¹⁰ represents a group having a π-conjugated system.

Examples of the electron-withdrawing group represented by A¹ or A² include a group represented by —CH═C(—CN)₂ and groups represented by the following Formulas (a-1) to (a-9).

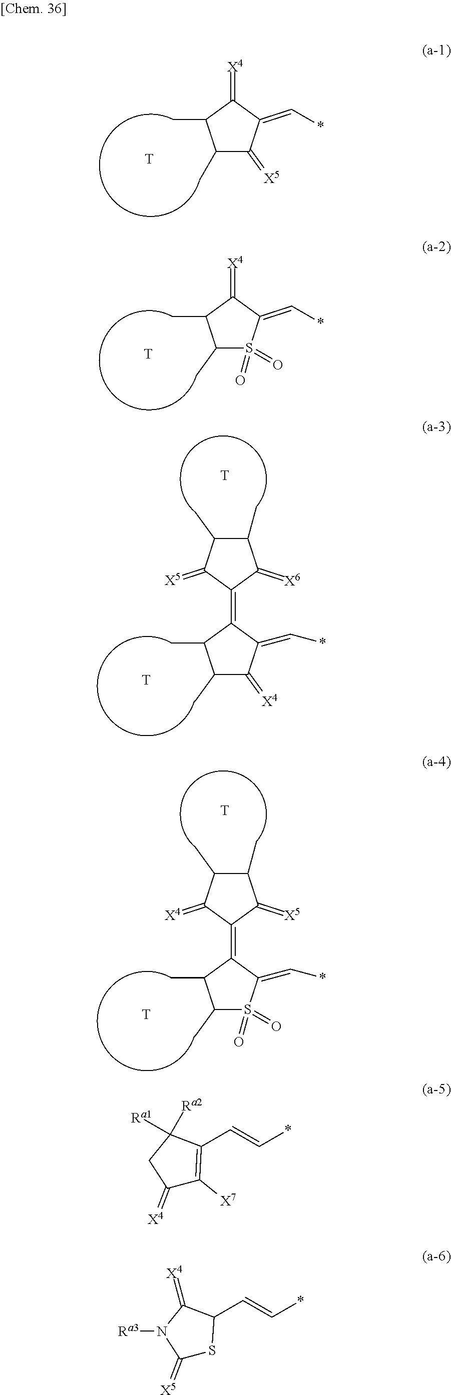

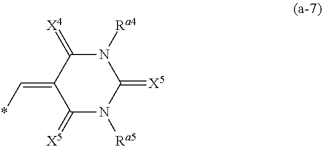

In Formulas (a-1) to (a-7),

T represents a carbocyclic ring which may have a substituent or a heterocyclic ring which may have a substituent. Each of the carbocyclic ring and the heterocyclic ring may be a single ring or a condensed ring. In a case where these rings have a plurality of substituents, the plurality of substituents may be the same as or different from each other.

Examples of the carbocyclic ring which is represented by T and may have a substituent include an aromatic carbocyclic ring, and an aromatic carbocyclic ring is preferable. Specific examples of the carbocyclic ring which is represented by T and may have a substituent include a benzene ring, a naphthalene ring, an anthracene ring, a tetracene ring, a pentacene ring, a pyrene ring, and a phenanthrene ring, a benzene ring, a naphthalene ring, and a phenanthrene ring are preferable, a benzene ring and a naphthalene ring are more preferable, and a benzene ring is still more preferable. These rings may have a substituent.

Examples of the heterocyclic ring which is represented by T and may have a substituent include an aromatic heterocyclic ring, and an aromatic heterocyclic ring is preferable. Specific examples of the heterocyclic ring which is represented by T and may have a substituent include a pyridine ring, a pyridazine ring, a pyrimidine ring, a pyrazine ring, a pyrrole ring, a furan ring, a thiophene ring, an imidazole ring, an oxazole ring, a thiazole ring, and a thienothiophene ring, a thiophene ring, a pyridine ring, a pyrazine ring, a thiazole ring, and a thienothiophene ring are preferable, and a thiophene ring is more preferable. These rings may have a substituent.

Examples of the substituent which may be included in the carbocyclic ring or heterocyclic ring represented by T include a halogen atom, an alkyl group, an alkyloxy group, an aryl group, and a monovalent heterocyclic group, and a fluorine atom and/or an alkyl group having 1 to 6 carbon atoms are preferable.

X⁴, X⁵, and X⁶ each independently represent an oxygen atom, a sulfur atom, an alkylidene group, or a group represented by ═C(—CN)₂, and are preferably an oxygen atom, a sulfur atom, or a group represented by ═C(—CN)₂.

X⁷ represents a hydrogen atom, a halogen atom, a cyano group, an alkyl group which may have a substituent, an alkyloxy group which may have a substituent, an aryl group which may have a substituent, or a monovalent heterocyclic group.

R^{a1}, R^{a2}, R^{a3}, R^{a4}, and R^{a5} each independently represent a hydrogen atom, an alkyl group which may have a substituent, a halogen atom, an alkyloxy group which may have a substituent, an aryl group which may have a substituent, or a monovalent heterocyclic group, and may be preferably an alkyl group which may have a substituent or an aryl group which may have a substituent.

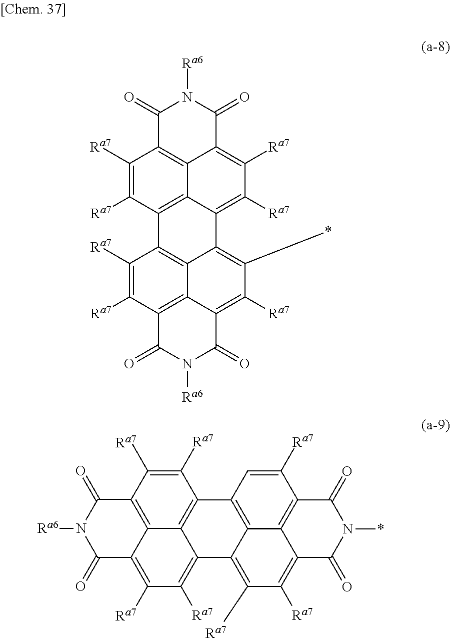

In Formulas (a-8) and (a-9), R^{a6} and R^{a7} each independently represent a hydrogen atom, a halogen atom, an alkyl group which may have a substituent, a cycloalkyl group which may have a substituent, an alkyloxy group which may have a substituent, a cycloalkyloxy group which may have a substituent, a monovalent aromatic carbocyclic group which may have a substituent, or a monovalent aromatic heterocyclic group which may have a substituent, and a plurality of R^{a6}'s and a plurality of R^{a7}'s may be the same as or different from each other.

The electron-withdrawing group represented by A¹ or A² is preferably a group represented by any one of the following Formulas (a-1-1) to (a-1-4) and (a-6-1) to (a-7-1), and is more preferably a group represented by Formula (a-1-1). Here, a plurality of R^{a10}'s each independently represent a hydrogen atom or a substituent, and preferably represent a hydrogen atom, a halogen atom, a cyano group, or an alkyl group which may have a substituent. R^{a3}, R^{a4}, and R^{a5} each independently have the same meaning as described above, and each independently preferably represent an alkyl group which may have a substituent or an aryl group which may have a substituent.

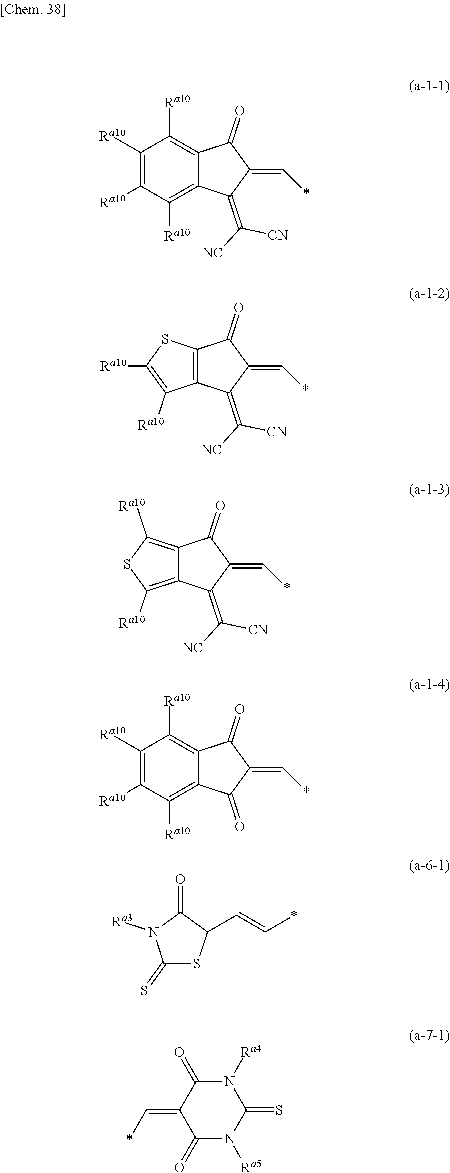

Examples of the group which is represented by B¹⁰ and has a π-conjugated system include a group represented by —(S¹)ₙ₁—B¹¹—(S²)ₙ₂— in a compound represented by Formula (VII) described below.

In the present embodiment, the n-type semiconductor material is preferably a compound represented by the following Formula (VII).

A¹-(S¹)ₙ₁—B¹¹—(S²)ₙ₂-A² (VII)

In Formula (VII), A¹ and A² each independently represent an electron-withdrawing group. Examples and preferred examples of A¹ and A² are the same as the examples and preferred examples described in A¹ and A² in Formula (VI).

S¹ and S² each independently represent a divalent carbocyclic group which may have a substituent, a divalent heterocyclic group which may have a substituent, or a group represented by —C(R^{s1})═C(R^{s2})— (where, R^{s1} and R^{s2} each independently represent a hydrogen atom, a substituent (preferably, a hydrogen atom, a halogen atom, an alkyl group which may have a substituent, or a monovalent heterocyclic group which may have a substituent), or a group represented by —C≡C—.

The divalent carbocyclic group which may have a substituent and the divalent heterocyclic group which may have a substituent may be fused rings, the divalent carbocyclic group and the divalent heterocyclic group being represented by S¹ or S². In a case where the divalent carbocyclic group or the divalent heterocyclic group has a plurality of substituents, the plurality of substituents may be the same as or different from each other.

In Formula (VII), n1 and n2 each independently represent an integer of 0 or more and preferably each independently represent 0 or 1, and both n1 and n2 more preferably represent 0 or 1.

Examples of the divalent carbocyclic group include a divalent aromatic carbocyclic group.

Examples of the divalent heterocyclic group include a divalent aromatic heterocyclic group.

In a case where the divalent aromatic carbocyclic group or the divalent aromatic heterocyclic group is a condensed ring, all of the rings constituting the condensed ring may be condensed rings having aromaticity, or only some rings constituting the condensed ring may be condensed rings having aromaticity.

Examples of S¹ and S² include a group represented by any one of Formulas (101) to (190) described as the examples of the divalent aromatic heterocyclic group represented by Ar³ described above, and a group in which a hydrogen atom in this group is substituted with a substituent.

S¹ and S² preferably each independently represent a group represented by the following Formula (s-1) or (s-2).

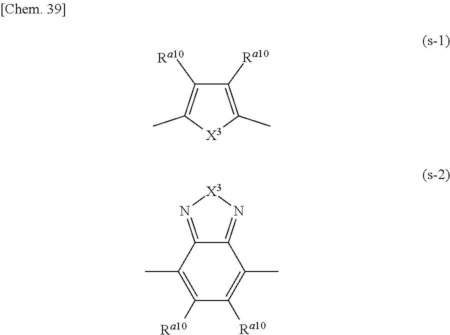

In Formulas (s-1) and (s-2),

X³ represents an oxygen atom or a sulfur atom.

R^{a10} is as defined above.

S¹ and S² preferably each independently represent a group represented by Formula (142), Formula (148), or Formula (184), or a group in which a hydrogen atom in this group is substituted with a substituent, and more preferably a group represented by Formula (142) or Formula (184), or a group in which one hydrogen atom in the group represented by Formula (184) is substituted with an alkyloxy group.

B¹¹ represents a condensed ring group having two or more structures selected from the group consisting of a carbocyclic structure and a heterocyclic structure, in which the condensed ring group does not have an ortho-peri-condensed structure and which may have a substituent.

The fused ring group represented by B¹¹ may have a structure in which two or more structures that are the same as each other are fused.

In a case where the fused ring group represented by B¹¹ has a plurality of substituents, the plurality of substituents may be the same as or different from each other.

Examples of a carbocyclic structure that constitutes the fused ring group represented by B¹¹ include a ring structure represented by the following Formula (Cy1) or (Cy2).

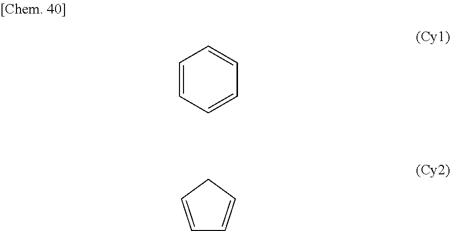 [SMILES: c1ccccc1 ; C1=CCC=C1]

Examples of a heterocyclic structure that constitutes the fused ring group represented by B¹¹ include a ring structure represented by any one of the following Formulas (Cy3) to (Cy10).

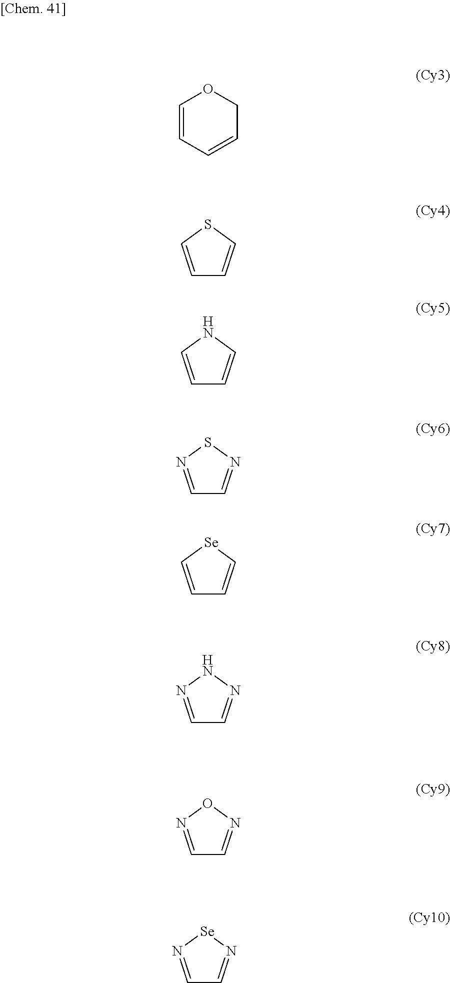

In Formula (VII), B¹¹ is preferably a fused ring group having two or more structures selected from the group consisting of structures represented by Formulas (Cy1) to (Cy10), a fused ring group that does not have an ortho-peri-fused structure, or a fused ring group which may have a substituent. B¹¹ may have a structure obtained by fusing two or more identical structures among the structures represented by Formulas (Cy1) to (Cy10).

B¹¹ is more preferably a fused ring group having two or more structures selected from the group consisting of structures represented by Formulas (Cy1) to (Cy6) and (Cy8), a fused ring group that does not have an ortho-peri-fused structure, or a fused ring group which may have a substituent.

The substituent which may be included in the condensed ring group and is represented by B¹¹ is preferably an alkyl group which may have a substituent, an aryl group which may have a substituent, an alkyloxy group which may have a substituent, or a monovalent heterocyclic group which may have a substituent. The aryl group which may be included in the condensed ring group represented by B¹¹ may be substituted with, for example, an alkyl group.

Examples of the condensed ring group represented by B¹¹ include groups represented by the following Formulas (b-1) to (b-13), and a group in which a hydrogen atom in this group is further substituted with a substituent (preferably, an alkyl group which may have a substituent, an aryl group which may have a substituent, an alkyloxy group which may have a substituent, or a monovalent heterocyclic group which may have a substituent).

As the fused ring group represented by B¹¹, a group represented by the following Formula (b-2) or (b-3), or a group in which a hydrogen atom in this group is further substituted with a substituent (preferably, an alkyl group which may have a substituent, an aryl group which may have a substituent, an alkyloxy group which may have a substituent, or a monovalent heterocyclic group which may have a substituent) is preferable, and a group represented by the following Formula (b-2) or (b-3) is more preferable.

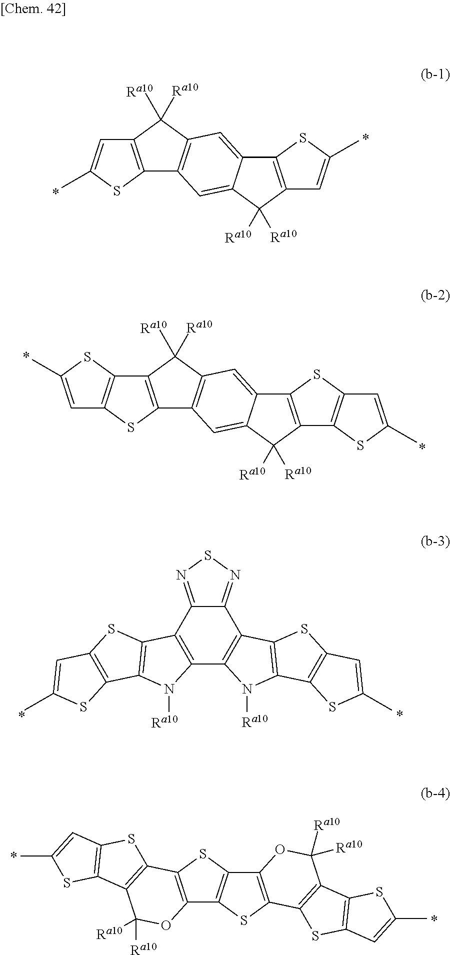

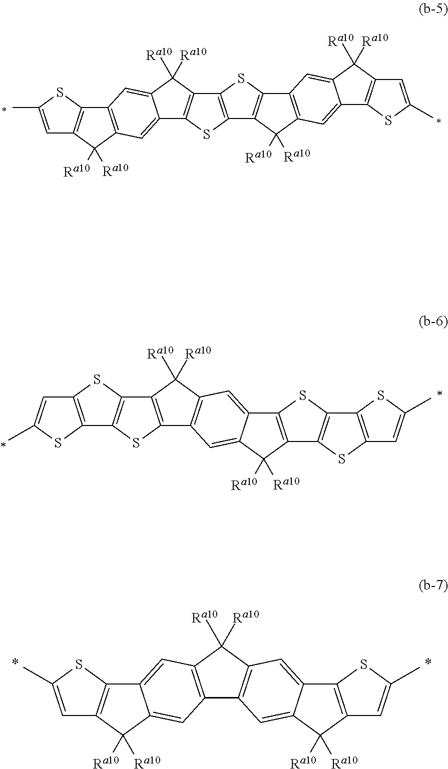

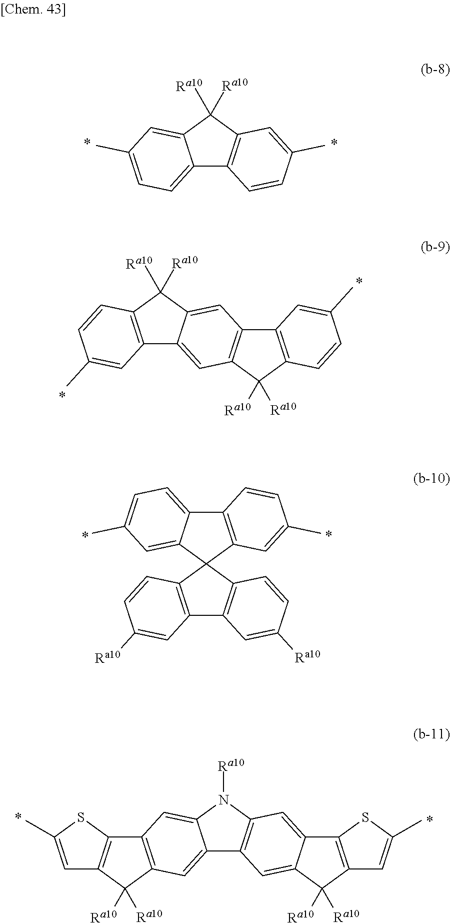

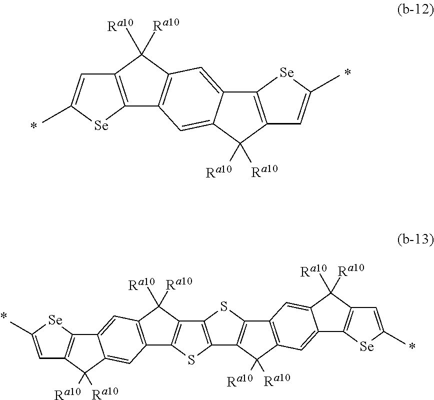

In Formulas (b-1) to (b-13),

R^{a10} is as defined above.

In Formulas (b-1) to (b-13), a plurality of R^{a10}'s are preferably each independently an alkyl group which may have a substituent or an aryl group which may have a substituent.

Examples of the compound represented by Formula (VI) or Formula (VII) include a compound represented by the following formula.

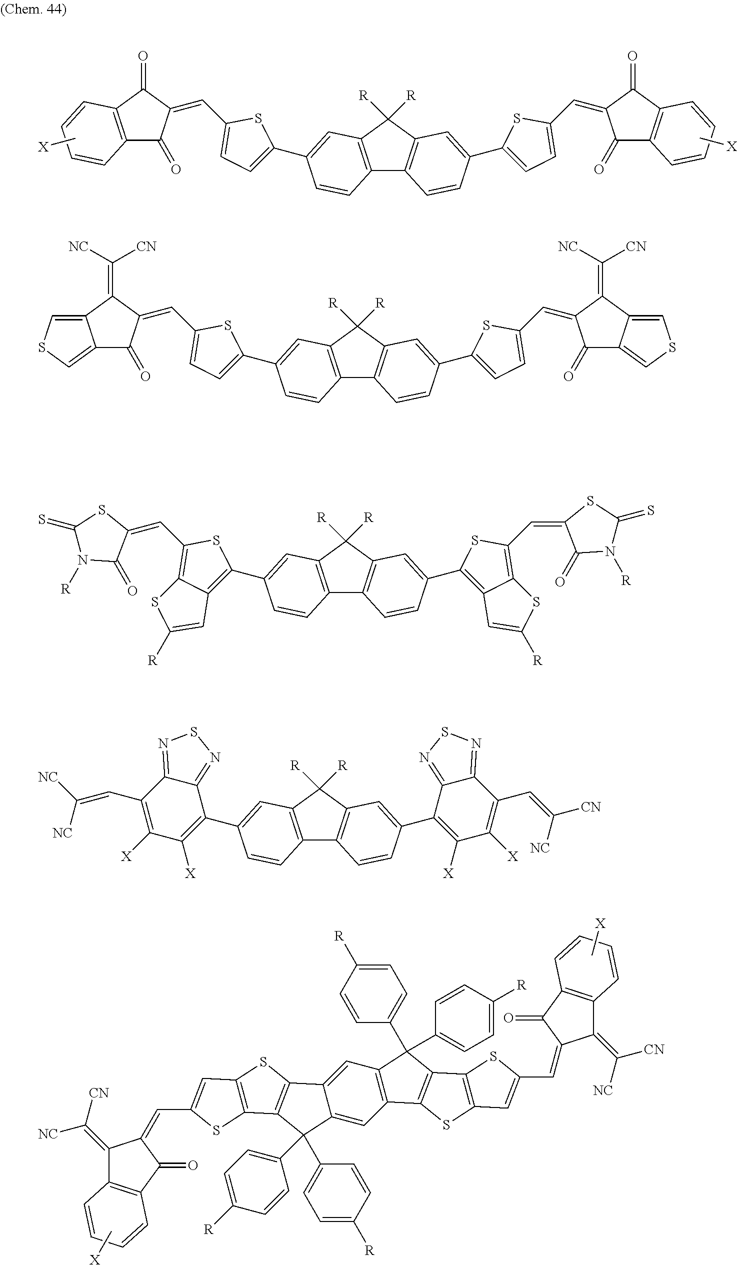

In the formulas, R is as defined above, and X represents a hydrogen atom, a halogen atom, a cyano group, or an alkyl group which may have a substituent.

In the formula, R is preferably a hydrogen atom, an alkyl group which may have a substituent, an aryl group which may have a substituent, or an alkyloxy group which may have a substituent.

The active layer according to the present embodiment may contain a combination of the non-fullerene compound and fullerene and/or a fullerene derivative (fullerene compound) as an n-type semiconductor.

Preferred specific examples of the n-type semiconductor included in the active layer according to the present embodiment include compounds represented by the following formulas.

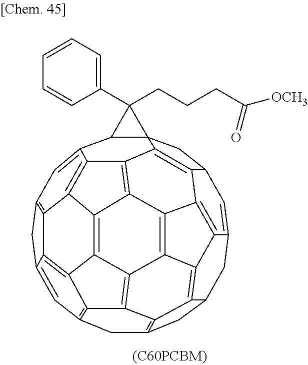 [SMILES: COC(=O)CCCC1(c2ccccc2)C2c3cc4c5c6c(cc7c8c9c%10c%11c%12c%13c%14c%15c(c%16c3c5c3c%16c%14c%12c9c3c68)C21CC%15C=C%13CC%11CC=%10C7)C4]

(Weight Ratio (p/n Ratio) of p-Type Semiconductor to n-Type Semiconductor)

A weight ratio of the p-type semiconductor to the n-type semiconductor (p-type semiconductor/n-type semiconductor) in the active layer is preferably 1/9 or more, more preferably 1/5 or more, and still more preferably 1/3 or more, but is preferably 9/1 or less, more preferably 5/1 or less, and still more preferably 3/1 or less. Here, when the active layer includes a plurality of p-type semiconductors, a weight of the p-type semiconductor is a total weight of the plurality of p-type semiconductors included in the active layer. In addition, when the active layer includes a plurality of n-type semiconductors, a weight of the n-type semiconductor is a total weight of the plurality of n-type semiconductors included in the active layer.

In the present embodiment, a thickness of the active layer is not particularly limited. The thickness of the active layer can be any suitable thickness in consideration of a balance between suppression of a dark current and extraction of a generated photocurrent. The thickness of the active layer is preferably 100 nm or more, more preferably 150 nm or more, and still more preferably 200 nm or more, particularly from the viewpoint of further reducing the dark current. In addition, the thickness of the active layer is preferably 10 μm or less, more preferably 5 μm or less, and still more preferably 1 μm or less.

### 3.5. Electron Transport Layer

As illustrated in FIG. 2, the photoelectric conversion element of the present embodiment preferably includes an electron transport layer provided between the second electrode and the active layer. The electron transport layer has a function of transporting electrons from the active layer to the second electrode. The electron transport layer may be in contact with the second electrode. The electron transport layer may be in contact with the active layer.

In another embodiment, the photoelectric conversion element may not include an electron transport layer.

The electron transport layer provided in contact with the second electrode may be particularly referred to as an electron injection layer. The electron transport layer (electron injection layer) provided in contact with the second electrode has a function of promoting injection of electrons generated in the active layer into the second electrode.

The electron transport layer contains an electron transporting material. Examples of the electron transporting material include polyalkyleneimine and a derivative thereof, a polymer compound having a fluorene structure, a metal such as calcium, and a metal oxide.

Examples of the polyalkyleneimine and the derivative thereof include a polymer having an alkyleneimine unit having 2 to 8 carbon atoms, such as polyethyleneimine, polypropyleneimine, polybutyleneimine, polydimethylethyleneimine, polypentyleneimine, polyhexyleneimine, polyheptyleneimine, or polyoctyleneimine, in particular, a polymer having an alkyleneimine unit having 2 to 4 carbon atoms, and a polymer chemically modified by reacting these polymers with various compounds. As the polyalkyleneimine and the derivative thereof, polyethyleneimine (PEI) and ethoxylated polyethyleneimine (PEIE) are preferable.

Examples of the polymer compound having a fluorene structure include poly[(9,9-bis(3′-(N,N-dimethylamino)propyl)-2,7-fluoren)-ortho-2,7-(9,9′-dioctylfluorene)] (PFN) and PFN-P2.

Examples of the metal oxide include zinc oxide, gallium-doped zinc oxide, aluminum-doped zinc oxide, titanium oxide, and niobium oxide. As the metal oxide, a metal oxide containing zinc is preferable, and zinc oxide is particularly preferable.

Examples of other electron transporting materials include poly(4-vinylphenol) and perylene diimide.

### 3.6. Sealing Member

It is preferable that the photoelectric conversion element of the present embodiment further includes a sealing member and is a sealing body sealed by a sealing body.

Any suitable conventionally known member can be used as the sealing member. Examples of the sealing member include a combination of a glass substrate as a substrate (sealing substrate) and a sealing material (adhesive) as a UV curable resin.

The sealing member may be a sealing layer having a layer structure of one or more layers. Examples of the layer constituting the sealing layer include a gas barrier layer and a gas barrier film.

The sealing layer is preferably formed of a material having a property of blocking moisture (water vapor barrier property) or a property of blocking oxygen (oxygen barrier property). Examples of a preferred material as the material of the sealing layer include an organic material such as polyethylene trifluoride, polytrifluoroethylene chloride (PCTFE), polyimide, polycarbonate, polyethylene terephthalate, alicyclic polyolefin, or an ethylene vinyl alcohol copolymer, and an inorganic material such as silicon oxide, silicon nitride, aluminum oxide, or diamond-like carbon.

The sealing member is usually formed of a material that can withstand a heat treatment performed when the sealing member is incorporated into a device to which a photoelectric conversion element is applied, for example, a device of an application example described below.

### 4. Modification

In the first embodiment, the photoelectric conversion element 10 is provided on the support substrate 11 so that the first electrode 12 is in contact with the support substrate 11.

In another embodiment, the photoelectric conversion element 10 may be provided on the support substrate 11 so that the second electrode 16 is in contact with the support substrate 11. That is, the support substrate 11, the second electrode 16, the electron transport layer 15, the active layer 14, the buffer layer 13, and the first electrode 12 may be arranged in this order.

### 5. Method for Manufacturing Photoelectric Conversion Element

The photoelectric conversion element of the present embodiment can be manufactured by any suitable conventionally known manufacturing method. The photoelectric conversion element of the present embodiment may be manufactured by combining steps suitable for the material selected for forming the constituent elements.

Hereinafter, as an embodiment of the present invention, a method for manufacturing a photoelectric conversion element having a configuration in which a substrate (support substrate), a first electrode, a buffer layer (electron blocking layer), an active layer, an electron transport layer, and a second electrode are in contact with each other in this order will be described.

### 5.1. Step of Preparing Substrate

In the present step, for example, a support substrate provided with a first electrode is prepared. In addition, it is possible to prepare a support substrate provided with a first electrode by obtaining a substrate provided with a conductive thin film formed of the electrode material described above from the market and patterning the conductive thin film to form the first electrode, if necessary.

In the method for manufacturing a photoelectric conversion element according to the present embodiment, the method for forming the first electrode in the case of forming the first electrode on the support substrate is not particularly limited. The first electrode can be formed on a structure (for example, a support substrate) in which the first electrode is to be formed using the material described above by any suitable conventionally known method such as a vacuum vapor deposition method, a sputtering method, an ion-plating method, a plating method, or a coating method.

### 5.2. Step of Forming Buffer Layer (Electron Blocking Layer)

The method for manufacturing a photoelectric conversion element according to the present embodiment includes a step of forming a buffer layer as an electron blocking layer provided between the active layer and the first electrode.

A method for forming the buffer layer is not particularly limited. For example, the buffer layer can be formed by a sputtering method (for example, a radio frequency (RF) sputtering method), a vacuum vapor deposition method, a coating method using a coating liquid containing a material that can form the buffer layer and a solvent, or the like. Specific examples of the coating method include a method in which a coating liquid containing a substance to be a precursor of the dielectric (D) is prepared, a coating film is formed by a coating method, and the coating film is fired to form a buffer layer including the dielectric (D).

### 5.3. Step of Forming Active Layer

In the method for manufacturing the photoelectric conversion element of the present embodiment, an active layer is formed on the electron blocking layer. The active layer can be formed by any suitable conventionally known forming step. In the present embodiment, the active layer can be produced by a coating method in which a coating liquid containing a component that can be contained in the active layer is applied onto the electron blocking layer. In the present embodiment, the active layer can be formed by a step including a step of applying an ink composition containing a p-type semiconductor, an n-type semiconductor, and a solvent onto the electron blocking layer to form a coating film, and a step of drying the coating film.

The ink composition for producing the active layer may contain an aromatic hydrocarbon as a solvent. The aromatic hydrocarbon may have a substituent. The aromatic hydrocarbon is particularly preferably a compound capable of dissolving the p-type semiconductor described above.

Examples of the aromatic hydrocarbon that can be used as a solvent include toluene, xylene (for example, o-xylene, m-xylene, or p-xylene), trimethylbenzene (for example, mesitylene or 1,2,4-trimethylbenzene (pseudocumene)), butylbenzene (for example, n-butylbenzene, sec-butylbenzene, or tert-butylbenzene), methylnaphthalene (for example, 1-methylnaphthalene), 1,2,3,4-tetrahydronaphthalene (tetralin), indane, 1-chloronaphthalene, chlorobenzene, and dichlorobenzene (for example, 1,2-dichlorobenzene).

The solvent may be composed of only one aromatic hydrocarbon or two or more aromatic hydrocarbons.

The ink composition for producing the active layer can contain an alkyl halide as a solvent. Examples of the alkyl halide that can be used as a solvent include chloroform.

In the ink composition for producing the active layer, in addition to the solvent (first solvent) described above, in particular, an additional solvent (second solvent) selected from the viewpoint of enhancing solubility of the n-type semiconductor material may be used in combination.

Examples of the additional solvent include an aromatic carbonyl compound, an aromatic ester compound, and a nitrogen-containing heterocyclic compound.

### (Weight Percentage of Solvent in Ink Composition)

When the total weight of the ink composition is 100 wt %, the total weight of the solvent contained in the ink composition is preferably 90 wt % or more, more preferably 92 wt % or more, and still more preferably 95 wt % or more, from the viewpoint of further improving solubility of each of the p-type semiconductor and the n-type semiconductor, but is preferably 99.9 wt % or less from the viewpoint of further increasing a concentration of each of the p-type semiconductor and the n-type semiconductor in the ink composition and easily forming a layer having a predetermined thickness or more.

In the ink composition, the p-type semiconductor and the n-type semiconductor may be dissolved or dispersed. In the ink composition, at least a part of each of the p-type semiconductor and the n-type semiconductor may be dissolved, or all of the p-type semiconductor and the n-type semiconductor may be dissolved.

As a method for applying the ink composition to an object to be coated, any conventionally known coating method can be used. In the present embodiment, as the coating method, a slit coating method, a knife coating method, a spin coating method, a micro-gravure coating method, a gravure coating method, a bar coating method, an inkjet coating method, a nozzle coating method, or a capillary coating method is preferable, a slit coating method, a spin coating method, a capillary coating method, or a bar coating method is more preferable, and a slit coating method or a spin coating method is still more preferable.

Any suitable method can be used as a method for removing the solvent from the coating film of the ink composition. Examples of the method for removing the solvent include drying methods such as a hot air drying method, an infrared heating drying method, a flash lamp annealing drying method, and a reduced pressure drying method.

### 5.4. Step of Forming Electron Transport Layer

The method for manufacturing a photoelectric conversion element of the present embodiment may include a step of forming an electron transport layer (electron injection layer) provided so as to be in contact with the active layer.

A method for forming the electron transport layer is not particularly limited. From the viewpoint of further simplifying the step of forming the electron transport layer, it is preferable to form an electron transport layer by any suitable conventionally known coating method. The electron transport layer can be formed, for example, by a coating method using a coating liquid containing the material that can constitute the electron transport layer described above and a solvent or a vacuum vapor deposition method.

### 5.5. Step of Forming Second Electrode

A method for forming the second electrode is not particularly limited. The second electrode can be formed using the electrode material exemplified above by any suitable conventionally known method such as a coating method, a vacuum vapor deposition method, a sputtering method, an ion-plating method, or a plating method. Through the steps described above, the photoelectric conversion element of the present embodiment is manufactured.

### 5.6. Step of Forming Sealing Body

In the present embodiment, when forming a sealing body, any suitable conventionally known sealing material (adhesive) and substrate (sealing substrate) are used. Specifically, a sealing material such as a UV curable resin is applied onto the support substrate so as to surround the periphery of the manufactured photoelectric conversion element, bonding is performed with the sealing material without a gap, and then, the photoelectric conversion element is sealed in a gap between the support substrate and the sealing substrate using a method suitable for the selected sealing material such as irradiation with UV rays, such that a sealing body of the photoelectric conversion element can be obtained.

### 6. Applications of Photoelectric Conversion Element

Examples of applications of the photoelectric conversion element of the present embodiment include a photodetector and a solar cell.

More specifically, the photoelectric conversion element of the present embodiment can allow a photocurrent to flow by irradiating light from the transparent or translucent electrode in a state in which a voltage (reverse bias voltage) is applied between the electrodes, and can be operated as a photodetector (photosensor). In addition, the photodetector can also be used as an image sensor by integrating a plurality of photodetectors. The photoelectric conversion element of the present embodiment can be particularly suitably used as a photodetector.

In addition, the photoelectric conversion element of the present embodiment can generate photovoltaic power between the electrodes by being irradiated with light, and can be operated as a solar cell. A solar cell module can also be formed by integrating a plurality of photoelectric conversion elements.

### 7. Application Examples of Photoelectric Conversion Element

The photoelectric conversion element according to the present embodiment can be suitably applied, as a photodetector, to a detection unit included in various electronic devices such as a workstation, a personal computer, a portable information terminal, an access management system, a digital camera, and a medical device.

The photoelectric conversion element of the present embodiment is included in the above-described exemplary electronic devices, and can be preferably applied to, for example, an image detection unit (for example, an image sensor such as an X-ray sensor) for a solid-state imaging device such as an X-ray imaging device or a CMOS image sensor, a detection unit (for example, a near-infrared sensor) of a biometric information authentication device that detects a predetermined feature of a part of a living body such as a fingerprint detection unit, a face detection unit, a vein detection unit, or an iris detection unit, and a detection unit of an optical biosensor such as a pulse oximeter.

The photoelectric conversion element of the present embodiment can also be suitably applied to a time-of-flight (TOF) type distance measuring device (TOF type distance measuring device) as an image detection unit for a solid-state imaging device.

In the TOF type distance measuring device, a distance is measured by allowing the photoelectric conversion element to receive reflected light obtained by reflection of light emitted from a light source on an object to be measured. Specifically, the distance to the object to be measured is determined by detecting the flight time until the irradiation light emitted from the light source is reflected by the object to be measured and returns as reflected light. The TOF type includes a direct TOF method and an indirect TOF method. In the direct TOF method, a difference between the time when light is emitted from the light source and the time when the reflected light is received by the photoelectric conversion element is directly measured, and in the indirect TOF method, a distance is measured by converting a change in charge accumulation amount depending on the flight time into a time change. As a distance measuring principle for obtaining a flight time by charge accumulation used in the indirect TOF method, there are a continuous wave (in particular, sinusoidal wave) modulation method and a pulse modulation method for obtaining a flight time from phases of light emitted from a light source and reflected light reflected by an object to be measured.

Hereinafter, among the detection units to which the photoelectric conversion element according to the present embodiment can be suitably applied, configuration examples of an image detection unit for a solid-state imaging device and an image detection unit for an X-ray imaging device, a fingerprint detection unit and a vein detection unit for a biometric authentication device (for example, a fingerprint authentication device, a vein authentication device, or the like), and an image detection unit of a TOF type distance measuring device (indirect TOF method) will be described with reference to the drawings.

### (Image Detection Unit for Solid-State Imaging Device)

FIG. 5 is a view schematically illustrating a configuration example of an image detection unit for a solid-state imaging device.

An image detection unit 1 includes a CMOS transistor substrate 20, an interlayer insulating film 30 provided so as to cover the CMOS transistor substrate 20, a photoelectric conversion element 10 according to the embodiment of the present invention provided on the interlayer insulating film 30, an interlayer wiring portion 32 provided so as to penetrate through the interlayer insulating film 30 and electrically connecting the CMOS transistor substrate 20 and the photoelectric conversion element 10, a sealing layer 40 provided so as to cover the photoelectric conversion element 10, and a color filter 50 provided on the sealing layer 40.

The CMOS transistor substrate 20 is included in a form according to a design with any suitable conventionally known configuration.

The CMOS transistor substrate 20 includes a functional element such as a CMOS transistor circuit (MOS transistor circuit) for realizing various functions that includes a transistor, a capacitor, and the like formed in a thickness of the substrate.

Examples of the functional element include a floating diffusion, a reset transistor, an output transistor, and a selection transistor.

With such a functional element, a wiring, and the like, a signal reading circuit and the like are built in the CMOS transistor substrate 20.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

The sealing layer 40 can be formed of any suitable conventionally known material under a condition in which permeation of harmful substances such as oxygen and water that may cause functional deterioration of the photoelectric conversion element 10 can be prevented or suppressed. The sealing layer 40 can have the same configuration as that of the sealing member 17 described above.

As the color filter 50, for example, a primary color filter formed of any suitable conventionally known material and corresponding to the design of the image detection unit 1 can be used. In addition, as the color filter 50, a complementary color filter capable of reducing the thickness as compared with the primary color filter can also be used. As the complementary color filter, for example, a color filter in which three types of (yellow, cyan, and magenta), three types of (yellow, cyan, and transparent), three types of (yellow, transparent, magenta), and three types of (transparent, cyan, and magenta) are combined can be used. This color filter can be arbitrarily preferably arranged corresponding to the design of the photoelectric conversion element 10 and the CMOS transistor substrate 20 on the condition that the color image data can be generated.

Light received by the photoelectric conversion element 10 through the color filter 50 is converted into an electrical signal according to the amount of received light by the photoelectric conversion element 10, and is output to the outside of the photoelectric conversion element 10 through the electrodes as a light reception signal, that is, an electrical signal corresponding to an imaging target.

Then, the light reception signal output from the photoelectric conversion element 10 is input to the CMOS transistor substrate 20 via the interlayer wiring portion 32, is read by the signal reading circuit built in the CMOS transistor substrate 20, and is subjected to signal processing by a further suitable conventionally known functional unit (not illustrated), such that image information is generated based on the imaging target.

### (Fingerprint Detection Unit)

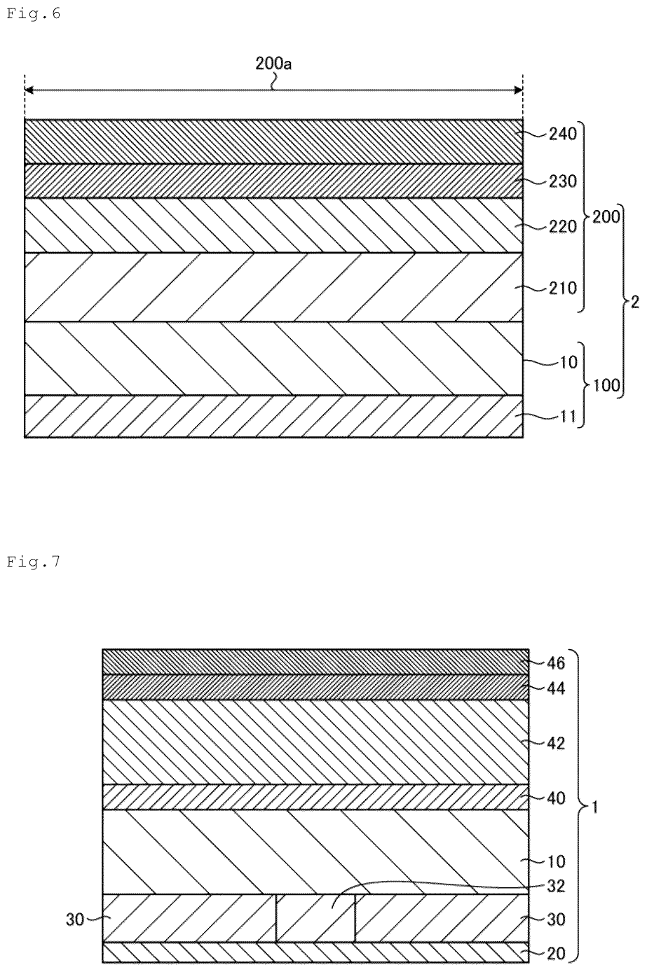

FIG. 6 is a view schematically illustrating a configuration example of a fingerprint detection unit integrally configured in a display device.

A display device 2 of a portable information terminal includes a fingerprint detection unit 100 including the photoelectric conversion element 10 according to the embodiment of the present invention as a main constituent element, and a display panel unit 200 provided on the fingerprint detection unit 100 and displaying a predetermined image.

In this configuration example, the fingerprint detection unit 100 is provided in an area coinciding with a display area 200a of the display panel unit 200. In other words, the display panel unit 200 is integrally laminated on the fingerprint detection unit 100.

In a case where the fingerprint detection is performed only in a partial area of the display area 200a, the fingerprint detection unit 100 may be provided corresponding to only the partial area.

The fingerprint detection unit 100 includes the photoelectric conversion element 10 according to the present embodiment of the present invention as a functional unit exhibiting an essential function. The fingerprint detection unit 100 can include any suitable conventionally known member such as a protection film, a support substrate, a sealing substrate, a sealing member, a barrier film, a bandpass filter, or an infrared cut film (not illustrated) in a form corresponding to a design that can obtain desired characteristics. The configuration of the image detection unit described above can also be adopted for the fingerprint detection unit 100.

The photoelectric conversion element 10 can be included in the display area 200a in any form. For example, a plurality of photoelectric conversion elements 10 may be arranged in a matrix.

As described above, the photoelectric conversion element 10 is provided on the support substrate 11, and electrodes (first electrode and second electrode) are provided in the support substrate 11 in, for example, a matrix.

The light received by the photoelectric conversion element 10 is converted into an electrical signal according to the amount of received light by the photoelectric conversion element 10, and is output to the outside of the photoelectric conversion element 10 through the electrodes as a light reception signal, that is, an electrical signal corresponding to an imaged fingerprint.

In this configuration example, the display panel unit 200 is configured as an organic electroluminescent display panel (organic EL display panel) including a touch sensor panel. For example, instead of the organic EL display panel, the display panel unit 200 may be configured as a display panel having any suitable conventionally known configuration such as a liquid crystal display panel including a light source such as a backlight.

The display panel unit 200 is provided on the fingerprint detection unit 100 described above. The display panel unit 200 includes an organic electroluminescent element (organic EL element) 220 as a functional unit exhibiting an essential function. The display panel unit 200 may further include any suitable conventionally known member such as a substrate (a support substrate 210 or a sealing substrate 240) such as a suitable conventionally known glass substrate, a sealing member, a barrier film, a polarizing plate such as a circular polarizing plate, or a touch sensor panel 230, in a form corresponding to desired characteristics.

In the configuration examples described above, the organic EL element 220 is used as a light source of a pixel in the display area 200a, and is also used as a light source for imaging a fingerprint in the fingerprint detection unit 100.

Here, an operation of the fingerprint detection unit 100 will be briefly described.

At the time of executing fingerprint authentication, the fingerprint detection unit 100 detects a fingerprint using light emitted from the organic EL element 220 of the display panel unit 200. Specifically, the light emitted from the organic EL element 220 passes through a constituent element existing between the organic EL element 220 and the photoelectric conversion element 10 of the fingerprint detection unit 100, and is reflected by the skin (finger surface) of the fingertip of the finger placed so as to be in contact with a surface of the display panel unit 200 in the display area 200a. At least a part of the light reflected by the finger surface is transmitted through the constituent element existing between the organic EL element 220 and the photoelectric conversion element 10, and is converted into an electrical signal corresponding to the amount of light received by the photoelectric conversion element 10. Then, image information on the fingerprint of the finger surface is obtained from the converted electrical signal.

The portable information terminal including the display device 2 performs fingerprint authentication by comparing the obtained image information with previously recorded fingerprint data for fingerprint authentication by any suitable conventionally known step.

### (Image Detection Unit for X-Ray Imaging Device)

FIG. 7 is a view schematically illustrating a configuration example of an image detection unit for an X-ray imaging device.

An image detection unit 1 for an X-ray imaging device includes a CMOS transistor substrate 20, an interlayer insulating film 30 provided so as to cover the CMOS transistor substrate 20, a photoelectric conversion element 10 according to the embodiment of the present invention provided on the interlayer insulating film 30, an interlayer wiring portion 32 provided so as to penetrate through the interlayer insulating film 30 and electrically connecting the CMOS transistor substrate 20 and the photoelectric conversion element 10, a sealing layer 40 provided so as to cover the photoelectric conversion element 10, a scintillator 42 provided on the sealing layer 40, a reflective layer 44 provided so as to cover the scintillator 42, and a protective layer 46 provided so as to cover the reflective layer 44.

The CMOS transistor substrate 20 is included in a form according to a design with any suitable conventionally known configuration.

The CMOS transistor substrate 20 includes a functional element such as a CMOS transistor circuit (MOS transistor circuit) for realizing various functions that includes a transistor, a capacitor, and the like formed in a thickness of the substrate.

Examples of the functional element include a floating diffusion, a reset transistor, an output transistor, and a selection transistor.

With such a functional element, a wiring, and the like, a signal reading circuit and the like are built in the CMOS transistor substrate 20.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

The sealing layer 40 can be formed of any suitable conventionally known material under a condition in which permeation of harmful substances such as oxygen and water that may cause functional deterioration of the photoelectric conversion element 10 can be prevented or suppressed. The sealing layer 40 can have the same configuration as that of the sealing member 17 described above.

The scintillator 42 can be formed of any suitable conventionally known material corresponding to the design of the image detection unit 1 for an X-ray imaging device. Examples of the suitable material for the scintillator 42 include inorganic crystals of inorganic materials such as cesium iodide (CsI), sodium iodide (NaI), zinc sulfide (ZnS), gadolinium oxysulfide (GOS), and gadolinium silicate (GSO), organic crystals of organic materials such as anthracene, naphthalene, and stilbene, an organic liquid obtained by dissolving an organic material such as diphenyl oxazole (PPO) or terphenyl (TP) in an organic solvent such as toluene, xylene, and dioxane, gas such as xenon or helium, and plastic.

The constituent elements described above can be arranged in any suitable manner corresponding to the design of the photoelectric conversion element 10 and the CMOS transistor substrate 20 under a condition in which the scintillator 42 can convert the incident X-ray into light having a wavelength centered on the visible region to generate image data.

The reflective layer 44 reflects light converted by the scintillator 42. The reflective layer 44 can reduce a loss of the converted light and increase detection sensitivity. In addition, the reflective layer 44 can also block light directly incident from the outside.

The protective layer 46 can be formed of any suitable conventionally known material under a condition in which permeation of harmful substances such as oxygen and water that may cause functional deterioration of the scintillator 42 can be prevented or suppressed.

Here, the operation of the image detection unit 1 for an X-ray imaging device having the configuration described above will be briefly described.

When radiation energy such as X-rays or Y-rays is incident on the scintillator 42, the scintillator 42 absorbs the radiation energy and converts the radiation energy into light (fluorescence) having a wavelength from ultraviolet to infrared regions centered on the visible region. Then, the light converted by the scintillator 42 is received by the photoelectric conversion element 10.

As described above, light received by the photoelectric conversion element 10 through the scintillator 42 is converted into an electrical signal according to the amount of received light by the photoelectric conversion element 10, and is output to the outside of the photoelectric conversion element 10 through the electrodes as a light reception signal, that is, an electrical signal corresponding to an imaging target. The radiation energy (X-ray) to be detected may be incident from either the scintillator 42 or the photoelectric conversion element 10.

Then, the light reception signal output from the photoelectric conversion element 10 is input to the CMOS transistor substrate 20 via the interlayer wiring portion 32, is read by the signal reading circuit built in the CMOS transistor substrate 20, and is subjected to signal processing by a further suitable conventionally known functional unit (not illustrated), such that image information is generated based on the imaging target.

### (Vein Detection Unit)

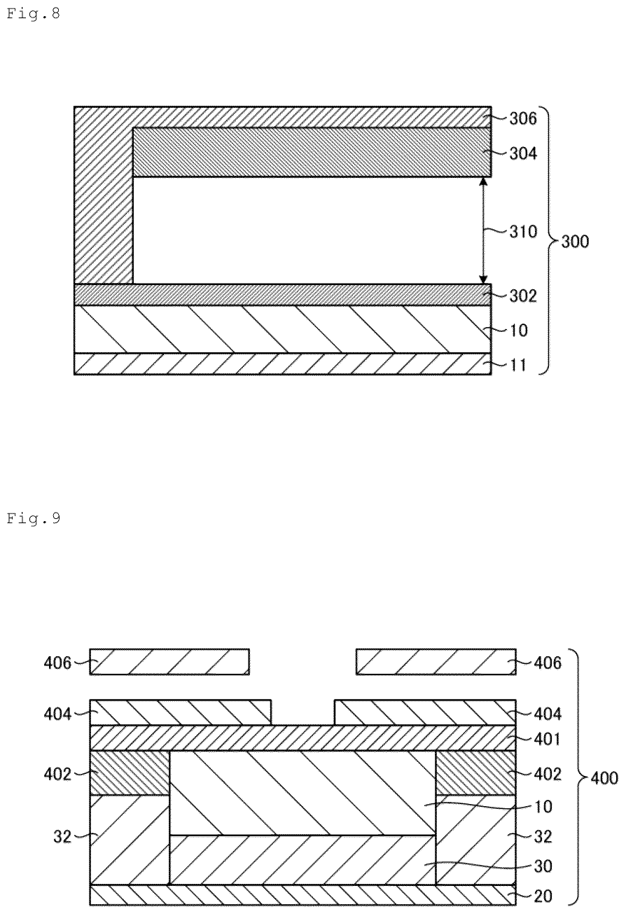

FIG. 8 is a view schematically illustrating a configuration example of a vein detection unit for a vein authentication device.

A vein detection unit 300 for a vein authentication device includes a cover portion 306 that partitions an insertion portion 310 into which a finger (for example, one or more fingertips, fingers, and palms) that is an object to be measured is inserted at the time of measurement, a light source portion 304 that is provided on the cover portion 306 and irradiates the object to be measured with light, a photoelectric conversion element 10 that receives the light emitted from the light source portion 304 through the object to be measured, a support substrate 11 that supports the photoelectric conversion element 10, and a glass substrate 302 that is arranged so as to face the support substrate 11 with the photoelectric conversion element 10 interposed therebetween, is spaced apart from the cover portion 306 at a predetermined distance, and partitions the insertion portion 310 together with the cover portion 306.

In this configuration example, the light source portion 304 is a transmission imaging system in which the light source portion is integrated with the cover portion 306 so as to be spaced apart from the photoelectric conversion element 10 with the object to be measured interposed therebetween during use, but the light source portion 304 is not necessarily located on the cover portion 306.

Under a condition in which the object to be measured can be efficiently irradiated with the light emitted from the light source portion 304, for example, a reflection imaging system of irradiating the object to be measured from the photoelectric conversion element 10 may be adopted.

The vein detection unit 300 includes the photoelectric conversion element 10 according to the present embodiment of the present invention as a functional unit exhibiting an essential function. The vein detection unit 300 can include any suitable conventionally known member such as a protection film, a sealing member, a barrier film, a bandpass filter, a near infrared transmission filter, a visible light cut film, or a finger placement guide (not illustrated) in a form corresponding to a design that can obtain desired characteristics. The configuration of the image detection unit 1 described above can also be adopted for the vein detection unit 300.

The photoelectric conversion element 10 can be included in any form. For example, a plurality of photoelectric conversion elements 10 may be arranged in a matrix.

As described above, the photoelectric conversion element 10 is provided on the support substrate 11, and electrodes (first electrode and second electrode) are provided in the support substrate 11 in, for example, a matrix.

The light received by the photoelectric conversion element 10 is converted into an electrical signal according to the amount of received light by the photoelectric conversion element 10, and is output to the outside of the photoelectric conversion element 10 through the electrodes as a light reception signal, that is, an electrical signal corresponding to an imaged vein.

At the time of vein detection (at the time of use), the object to be measured may or may not be in contact with the glass substrate 302 provided on the photoelectric conversion element 10.

Here, an operation of the vein detection unit 300 will be briefly described.

At the time of vein detection, the vein detection unit 300 detects a vein pattern of the object to be measured using light emitted from the light source portion 304. Specifically, the light emitted from the light source portion 304 passes through the object to be measured and is converted into an electrical signal corresponding to the amount of light received by the photoelectric conversion element 10. Then, image information on the vein pattern of the object to be measured is obtained from the converted electrical signal.

In the vein authentication device, vein authentication is performed by comparing the obtained image information with the vein data for the vein authentication recorded in advance by any suitable conventionally known step.

### (Image Detection Unit for TOF Type Distance Measuring Device)

FIG. 9 is a view schematically illustrating a configuration example of an image detection unit for an indirect time-of-flight (TOF) type distance measuring device.

An image detection unit 400 for a TOF type distance measuring device includes a CMOS transistor substrate 20, an interlayer insulating film 30 provided so as to cover the CMOS transistor substrate 20, a photoelectric conversion element 10 according to the embodiment of the present invention provided on the interlayer insulating film 30, two floating diffusion layers 402 arranged to be spaced from each other so as to interpose the photoelectric conversion element 10 therebetween, an insulating layer 401 provided so as to cover the photoelectric conversion element 10 and the floating diffusion layer 402, and two photo-gates 404 provided on the insulating layer 401 and arranged to be spaced apart from each other.

A part of the insulating layer 401 is exposed from a gap between the two photo-gates 404 spaced apart from each other, and the remaining region is shielded from light by a light shielding portion 406. The CMOS transistor substrate 20 and the floating diffusion layer 402 are electrically connected by an interlayer wiring portion 32 provided so as to penetrate the interlayer insulating film 30.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

In this configuration example, the insulating layer 401 can have any suitable conventionally known configuration such as a field oxide film formed of silicon oxide.

The photo-gate 404 can be formed of any suitable conventionally known material such as polysilicon.

The image detection unit 400 for a TOF type distance measuring device includes the photoelectric conversion element 10 according to the embodiment of the present invention as a functional unit exhibiting an essential function. The image detection unit 400 for a TOF type distance measuring device can include any suitable conventionally known member such as a protection film, a support substrate, a sealing substrate, a sealing member, a barrier film, a bandpass filter, or an infrared cut film (not illustrated) in a form corresponding to a design that can obtain desired characteristics.

Here, an operation of the image detection unit 400 for a TOF type distance measuring device will be briefly described.

Light is emitted from a light source, the light emitted from the light source is reflected by an object to be measured, and the reflected light is received by the photoelectric conversion element 10. The two photo-gates 404 are provided between the photoelectric conversion element 10 and the floating diffusion layer 402, and pulses are alternately applied, such that signal charges generated by the photoelectric conversion element 10 are transferred to one of the two floating diffusion layers 402, and charges are accumulated in the floating diffusion layers 402. When light pulses arrive so as to spread equally with respect to the timing at which the two photo-gates 404 are opened, the amounts of charges accumulated in the two floating diffusion layers 402 become equal. When the light pulses arrive at the other photo-gate 404 later than the timing at which the light pulses arrive at the one photo-gate 404, a difference in the amounts of charges accumulated in the two floating diffusion layers 402 occurs.

The difference in the amount of charges accumulated in the floating diffusion layer 402 depends on the delay time of the light pulse. Since a distance L to the object to be measured has a relationship of L=(1/2)ctd using a round-trip time of light td and a velocity of light c, when the delay time can be estimated from the difference in the amounts of charges accumulated in the two floating diffusion layers 402, the distance to the object to be measured can be determined.

The amount of light received by the photoelectric conversion element 10 is converted into an electrical signal as the difference in the amounts of charges accumulated in the two floating diffusion layers 402, and is output to the outside of the photoelectric conversion element 10 as a light reception signal, that is, an electrical signal corresponding to the object to be measured.

Then, the light reception signal output from the floating diffusion layers 402 is input to the CMOS transistor substrate 20 via the interlayer wiring portion 32, is read by the signal reading circuit built in the CMOS transistor substrate 20, and is further subjected to signal processing by any suitable conventionally known functional unit (not illustrated), such that distance information is generated based on the object to be measured.

### 8. Photodetector

As described above, the photoelectric conversion element of the present embodiment can have a photodetection function capable of converting the emitted light into an electrical signal according to the amount of received light and outputting the electrical signal to an external circuit through the electrode. Therefore, the photoelectric conversion element according to the embodiment of the present invention can be particularly suitably applied as a photodetector having a photodetection function. Here, the photodetector of the present embodiment may be a photoelectric conversion element itself, and may further include a functional element for voltage control or the like in addition to the photoelectric conversion element.

### EXAMPLES

Hereinafter, Examples will be shown in order to describe the present invention in more detail. The present invention is not limited to the following Examples.

In the following description, “%” and “part(s)” representing amounts are based on weight unless otherwise specified. In addition, the operations described below were performed under the conditions of normal temperature (20° C.±15° C.) and normal pressure (1 atm) unless otherwise specified.

### Compound Used in Each Example

### p-Type Semiconductor

The p-type semiconductor materials used in Examples and Comparative Examples are shown below.

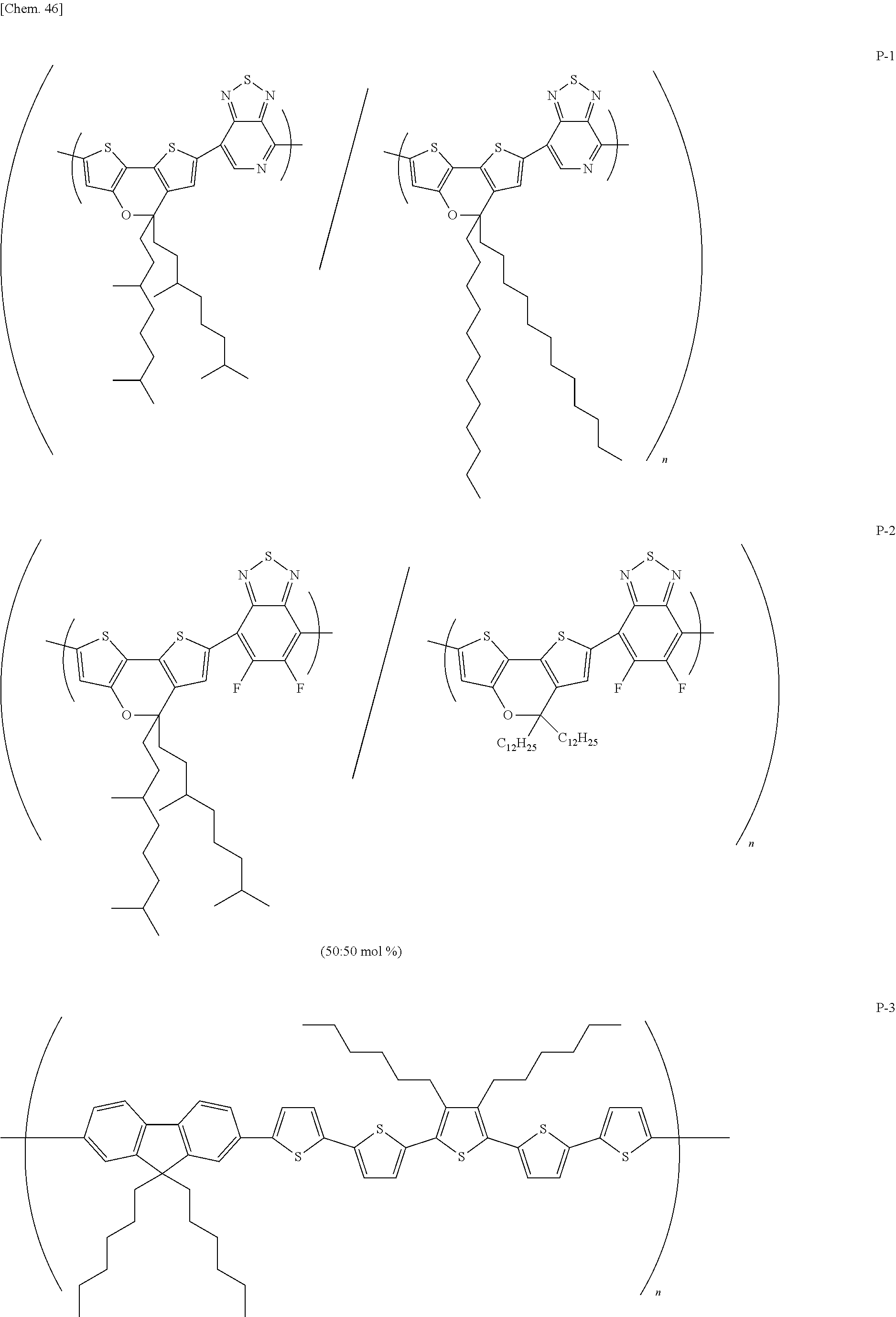

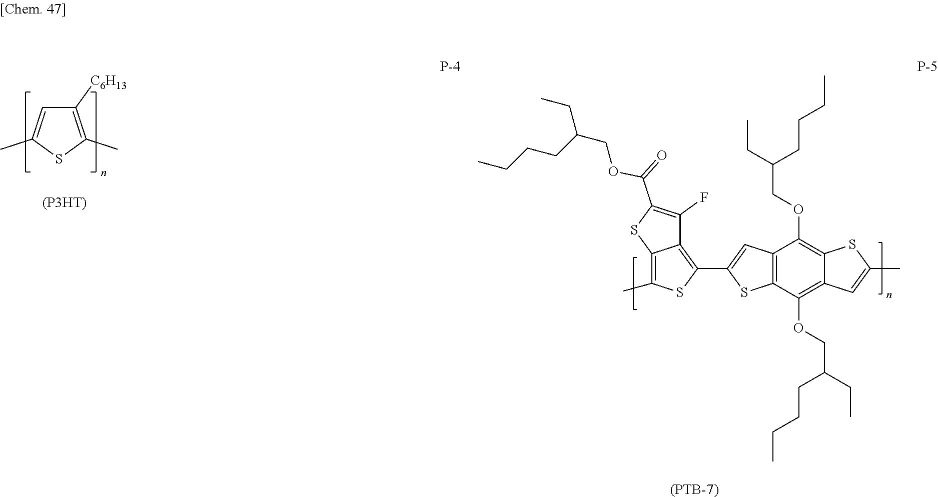

The polymer compound P-1 as a p-type semiconductor material is described in WO 2013/051676 A.

The materials were synthesized and used with reference to the described method.

The polymer compound P-2 as the p-type semiconductor material was synthesized with reference to the method described in WO 2011/052709 A and used.

The polymer compound P-3 as the p-type semiconductor material was synthesized with reference to the method described in JP-A-2007-529596.

As the polymer compound P-4 as the p-type semiconductor material, P3HT (trade name, manufactured by 1-Material Inc.) was obtained from the market and used.

As the polymer compound P-5 as the p-type semiconductor material, PTB7 (trade name, manufactured by 1-Material Inc.) was obtained from the market and used.

As the compound N-1 as an n-type semiconductor material, “Guard Surf NC-1010” (trade name) (manufactured by HARVES Co., Ltd.) was obtained from the market and used.

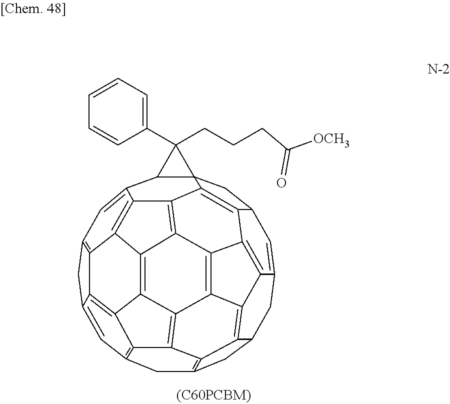 [SMILES: COC(=O)CCCC1(c2ccccc2)C2c3cc4c5c6c(cc7c8c9c%10c%11c%12c%13c%14c%15c(c%16c3c5c3c%16c%14c%12c9c3c68)C21CC%15C=C%13CC%11CC=%10C7)C4]

As the compound N-2 as an n-type semiconductor material, “C60PCBM (phenyl C61-butyric acid methyl ester)” (manufactured by Nano-C, Inc.) was obtained from the market and used.

### Method for Calculating LUMO Energy Level of p-Type Semiconductor Material

The energy levels (eV) of the LUMOs of the compounds P-1 to P-5 were calculated based on the values measured by ultraviolet photoelectron spectroscopy (UPS method). Hereinafter, the calculation method will be specifically described.

### (1) Sample Preparation

First, the compounds P-1 to P-5 were each dissolved in ortho-dichlorobenzene to obtain a solution. Next, each of the obtained solutions was applied onto a glass substrate by a spin coating method to form a coating film, and the solution was dried on a hot plate at 70° C. to form a layer having a thickness of 100 nm, thereby obtaining a sample.

### (2) Measurement of Energy Level of HOMO by UPS Method

For each of the obtained samples, the energy level of the HOMO of each of the (polymer) compounds P-1 to P-5 was calculated based on the number of electrons measured by a UPS method using a photoelectron spectrometer (Model AC-2 manufactured by RIKEN KEIKI CO., LTD.) in the air.

Here, the UPS method is a method for measuring the number of photoelectrons emitted with respect to the energy of the ultraviolet light radiated to the solid surface. From the minimum energy generated by the photoelectrons, the work function can be estimated when the sample is a metal, and the energy level of the HOMO can be estimated when the sample is a semiconductor material.

The energy level of the LUMO of each of the (polymer) compounds P-1 to P-5 can be calculated by the following equation.

$$Energy level of LUMO = Band gap ( Eg ) + Energy level of HOMO \qquad Equation$$

Here, the band gap (Eg) can be calculated by the following equation based on the absorption edge wavelength of the p-type semiconductor material.

$$Band gap ( Eg ) = hc / Absorption edge wavelength \qquad Equation$$

In the equation, h represents a Planck's constant (h=6.626×10⁻³⁴ Js) and c represents a speed of light

$$( c = 3 \times {10}^{8} m / s ) .$$

For the measurement of the absorption edge wavelength, a spectrophotometer (for example, ultraviolet-visible near-infrared spectrophotometer JASCO-V670, manufactured by JASCO Corporation) capable of measuring in wavelength regions of ultraviolet light, visible light, and near infrared light was used.

In the absorption spectrum obtained by the spectrophotometer, that is, the absorption spectrum shown by plotting the absorbance (absorption intensity) of the (polymer) compound on the vertical axis and the wavelength on the horizontal axis, the value of the wavelength at the intersection point between the baseline and the straight line fitted on the shoulder (high wavelength side) of the absorption peak was taken as the absorption edge wavelength (nm).

### Ec, Eg, and Relative Permittivity of Compound in Electron Blocking Layer

As the band gap Eg and the energy level Ec at the lower end of the conduction band of the compound (dielectric (D)) used for forming the electron blocking layer, values described in Document (1) (Document (D)) and Document (2) were used.
Document (1): Phys. ReV. B. 2008, 78, 085114 (related to HfO₂ and Zro₂, according to the method combining the UPS method and the IPS method)
Document (2): Adv. Mat. 2014, 26, 5670-5677 (related to WO₃, according to the UPS method)

In addition, as the relative permittivity of the compound (dielectric (D)) used for forming the electron blocking layer, the values described in Document (3) (Document (A)), Document (4), and Document (5) (Document (B)) were used.
Document (3): Thin Solid Films. 1977, 41, 247-259 (related to HfO₂)
Document (4): Physica B. 2012, 407, 4453-4457 (related to WO₃)
Document (5): J. App. Phys. 1985, 58, 2407 (related to Zro₂)

The respective values are shown in Table 1.

TABLE 1

| | Eg | Relative | Ec |
|---|---|---|---|
| | (eV) | permittivity | (eV) |
| Hafnium oxide (HfO₂) | 5.7 | 22 to 25 | −2.5 |
| Tungsten oxide (WO₃) | 3.0 | 2 × 10⁵ | −5.3 |
| Zirconium oxide (ZrO₂) | 5.5 | 21 | −2.7 |

### <Example 1> Manufacture and Evaluation of Photoelectric Conversion Element

### (Manufacture of Photoelectric Conversion Element)

An ITO thin film as a first electrode was formed in a thickness of 45 nm on a glass substrate by a sputtering method. The glass substrate was subjected to a surface treatment by an ozone UV treatment.

Next, a hafnium oxide (manufactured by Kojundo Chemical Lab. Co., Ltd.) film was formed as an electron blocking layer as a buffer layer on the ITO thin film of the glass substrate subjected to the ozone UV treatment by an RF sputtering method. A thickness of the buffer layer calculated from the film formation conditions was in a range of 5 nm to 10 nm.

Next, a polymer compound P-1 as a p-type semiconductor and a compound N-1 as an n-type semiconductor were mixed at a weight ratio of 1:1.5, the mixture was added to a mixed solvent 1 of tetralin as a first solvent and butyl benzoate as a second solvent (tetralin: butyl benzoate=97:3 (weight ratio)), and the mixture was stirred at 60° C. for 8 hours to prepare an active layer forming coating liquid 1.

The prepared active layer forming coating liquid 1 was applied onto the electron blocking layer of the glass substrate by a spin coating method to form a coating film. The formed coating film was dried for 5 minutes using a hot plate heated to 70° C. to form an active layer (a). A thickness of the formed active layer (a) was about 250 nm.

Next, a zinc oxide/3-pentanol dispersion (HTD-711Z manufactured by TAYCA Co., Ltd.) was applied onto the active layer (a) by a spin coating method as a coating liquid for forming an electron transport layer.

Next, a silver (Ag) layer having a thickness of about 60 nm was formed as a second electrode on the formed electron transport layer in a resistance heating vapor deposition apparatus to manufacture a photoelectric conversion element (photodetector).

Next, an ultraviolet (UV)-curable sealing agent was applied onto the glass substrate surrounding the manufactured photoelectric conversion element, the glass substrate as a sealing substrate was bonded, and then, the photoelectric conversion element was sealed by irradiation with UV light. The planar shape of the obtained photoelectric conversion element when viewed from a thickness direction was a square of 2 mm×2 mm.

The compounds used in the manufacture of the photoelectric conversion element are shown in Table 2.

### (Evaluation of Dark Current Before Heat Treatment of Photoelectric Conversion Element)

The manufactured photoelectric conversion element was subjected to JV measurement in a dark place to determine a dark current (Jd) at −5 V. JV measurement was performed using a source meter (Model 2450, manufactured by Keithley Instruments, LLC). The measurement results of Jd are shown in Table 3.

### (Evaluation of Dark Current After Heat Treatment of Photoelectric Conversion Element)

The manufactured photoelectric conversion element was subjected to a heat treatment at 180° C. for 10 minutes on a hot plate. Thereafter, a dark current (Jd) at −5 V was measured in the same manner as described above. The results are shown in Table 3.

### Example 2

A photoelectric conversion element was manufactured in the same manner that of Example 1, except that the following items were changed.
The p-type semiconductor was changed to the compound P-2.
The n-type semiconductor was changed to the compound N-2.
The mixed solvent 1 was changed to o-dichlorobenzene.

The obtained photoelectric conversion element was evaluated in the same manner as in Example 1. The compounds used in the manufacture of the photoelectric conversion element are shown in Table 2. The evaluation results are shown in Table 3.

### Example 3

A photoelectric conversion element was manufactured in the same manner that of Example 1, except that the following items were changed.
An electron blocking layer was formed using zirconium oxide (Zro₂) instead of hafnium oxide.

The obtained photoelectric conversion element was evaluated in the same manner as in Example 1. The compounds used in the manufacture of the photoelectric conversion element are shown in Table 2. The evaluation results are shown in Table 3.

### Example 4

A photoelectric conversion element was manufactured in the same manner that of Example 2, except that the following items were changed.
An electron blocking layer was formed using zirconium oxide (Zro₂) instead of hafnium oxide.

The obtained photoelectric conversion element was evaluated in the same manner as in Example 1. The compounds used in the manufacture of the photoelectric conversion element are shown in Table 2. The evaluation results are shown in Table 3.

### Comparative Example 1

A photoelectric conversion element was manufactured in the same manner that of Example 1, except that the following items were changed.
An active layer (a) was formed on an ITO thin film of a glass substrate subjected to an ozone UV treatment without forming an electron blocking layer.

The obtained photoelectric conversion element was evaluated in the same manner as in Example 1. The compounds used in the manufacture of the photoelectric conversion element are shown in Table 2. The evaluation results are shown in Table 3.

### Comparative Example 2

A photoelectric conversion element was manufactured in the same manner that of Example 2, except that the following items were changed.
An active layer (a) was formed on an ITO thin film of a glass substrate subjected to an ozone UV treatment without forming an electron blocking layer.

The obtained photoelectric conversion element was evaluated in the same manner as in Example 1. The compounds used in the manufacture of the photoelectric conversion element are shown in Table 2. The evaluation results are shown in Table 3.

### Comparative Example 3

A photoelectric conversion element was manufactured in the same manner that of Example 1, except that the following items were changed.
A tungsten oxide thin film (film formed by GEOMATEC Co., Ltd.) was formed as an electron blocking layer. The obtained photoelectric conversion element was evaluated in the same manner as in Example 1. The compounds used in the manufacture of the photoelectric conversion element are shown in Table 2. The evaluation results are shown in Table 3.

### Comparative Example 4

A photoelectric conversion element was manufactured in the same manner that of Example 2, except that the following items were changed.
The p-type semiconductor was changed to the compound P-3.

The obtained photoelectric conversion element was evaluated in the same manner as in Example 1. The compounds used in the manufacture of the photoelectric conversion element are shown in Table 2. The evaluation results are shown in Table 3.

### Comparative Example 5

A photoelectric conversion element was manufactured in the same manner that of Example 1, except that the following items were changed.
The p-type semiconductor was changed to the compound P-4.
The mixed solvent 1 was changed to o-dichlorobenzene.

The obtained photoelectric conversion element was evaluated in the same manner as in Example 1. The compounds used in the manufacture of the photoelectric conversion element are shown in Table 2. The evaluation results are shown in Table 3.

### Comparative Example 6

A photoelectric conversion element was manufactured in the same manner that of Example 2, except that the following items were changed.
The p-type semiconductor was changed to the compound P-5.

The obtained photoelectric conversion element was evaluated in the same manner as in Example 1. The compounds used in the manufacture of the photoelectric conversion element are shown in Table 2. The evaluation results are shown in Table 3.

### Comparative Example 7

A photoelectric conversion element was manufactured in the same manner that of Comparative Example 4, except that the following items were changed.
An electron blocking layer was formed using zirconium oxide (Zro₂) instead of hafnium oxide.

The obtained photoelectric conversion element was evaluated in the same manner as in Example 1. The compounds used in the manufacture of the photoelectric conversion element are shown in Table 2. The evaluation results are shown in Table 3.

### Comparative Example 8

A photoelectric conversion element was manufactured in the same manner that of Comparative Example 5, except that the following items were changed.
An electron blocking layer was formed using zirconium oxide (ZrO₂) instead of hafnium oxide.

The obtained photoelectric conversion element was evaluated in the same manner as in Example 1. The compounds used in the manufacture of the photoelectric conversion element are shown in Table 2. The evaluation results are shown in Table 3.

### Comparative Example 9

A photoelectric conversion element was manufactured in the same manner that of Comparative Example 6, except that the following items were changed.
An electron blocking layer was formed using zirconium oxide (ZrO₂) instead of hafnium oxide.

The obtained photoelectric conversion element was evaluated in the same manner as in Example 1. The compounds used in the manufacture of the photoelectric conversion element are shown in Table 2. The evaluation results are shown in Table 3.

TABLE 2

| | | | Electron | | |
|---|---|---|---|---|---|
| | p-Type | LUMO | blocking | Ec | Ec-LUMO |
| | semiconductor | (eV) | layer | (eV) | (eV) |
| Example 1 | P-1 | −3.9 | Hafnium | −2.5 | 1.4 |
| | | | oxide | | |
| Example 2 | P-2 | −3.8 | Hafnium | −2.5 | 1.3 |
| | | | oxide | | |
| Example 3 | P-1 | −3.9 | Zirconium | −2.7 | 1.2 |
| | | | oxide | | |
| Example 4 | P-2 | −3.8 | Zirconium | −2.7 | 1.1 |
| | | | oxide | | |
| Comparative | P-1 | −3.9 | — | | |
| Example 1 | | | | | |
| Comparative | P-2 | −3.8 | — | | |
| Example 2 | | | | | |
| Comparative | P-1 | −3.9 | Tungsten | −5.3 | −1.4 |
| Example 3 | | | oxide | | |
| Comparative | P-3 | −3.1 | Hafnium | −2.5 | 0.6 |
| Example 4 | | | oxide | | |
| Comparative | P-4 | −3.3 | Hafnium | −2.5 | 0.8 |
| Example 5 | | | oxide | | |
| Comparative | P-5 | −3.3 | Hafnium | −2.5 | 0.8 |
| Example 6 | | | oxide | | |
| Comparative | P-3 | −3.1 | Zirconium | −2.7 | 0.4 |
| Example 7 | | | oxide | | |
| Comparative | P-4 | −3.3 | Zirconium | −2.7 | 0.6 |
| Example 8 | | | oxide | | |
| Comparative | P-5 | −3.3 | Zirconium | −2.7 | 0.6 |
| Example 9 | | | oxide | | |

TABLE 3

| | | | | Dark current of photoelectric | |
|---|---|---|---|---|---|
| | | | | conversion element (nA/cm², | |
| | Active layer | | Electron | application of −5 V) | |
| | p-Type | n-Type | blocking | Before heat | After heat |
| | semiconductor | semiconductor | layer | treatment | treatment |
| Example 1 | P-1 | N-1 | Hafnium | 12 | 11 |
| | | | oxide | | |
| Example 2 | P-2 | N-2 | Hafnium | 11 | 9 |
| | | | oxide | | |
| Example 3 | P-1 | N-1 | Zirconium | 15 × 10¹ | 26 |
| | | | oxide | | |
| Example 4 | P-2 | N-2 | Zirconium | 13 | 26 |
| | | | oxide | | |
| Comparative | P-1 | N-1 | — | 27 | 24 × 10⁵ |
| Example 1 | | | | | |
| Comparative | P-2 | N-2 | — | 15 | 44 × 10⁷ |
| Example 2 | | | | | |
| Comparative | P-1 | N-1 | Tungsten | 15 | 11 × 10⁵ |
| Example 3 | | | oxide | | |
| Comparative | P-3 | N-2 | Hafnium | 20 | 77 × 10² |
| Example 4 | | | oxide | | |
| Comparative | P-4 | N-1 | Hafnium | 33 | 30 × 10² |
| Example 5 | | | oxide | | |
| Comparative | P-5 | N-2 | Hafnium | 16 | 29 × 10² |
| Example 6 | | | oxide | | |
| Comparative | P-3 | N-2 | Zirconium | 1.9 | 41 × 10² |
| Example 7 | | | oxide | | |
| Comparative | P-4 | N-1 | Zirconium | 20 | 54 × 10² |
| Example 8 | | | oxide | | |
| Comparative | P-5 | N-2 | Zirconium | 33 | 16 × 10² |
| Example 9 | | | oxide | | |

From the above results, it can be seen that the photoelectric conversion element according to each of Examples has a dark current value after the heat treatment that is equal to the dark current value before the heat treatment or does not greatly change from the value before the heat treatment, and has excellent heat resistance.

It can be seen that the photoelectric conversion element according to each of Comparative Examples has a dark current value after the heat treatment that is significantly increased from the dark current value before the heat treatment, and has poor heat resistance.

### DESCRIPTION OF REFERENCE SIGNS

1 Image detection unit
2 Display device
10 Photoelectric conversion element
11, 210 Support substrate
12 First electrode
13 Buffer layer (electron blocking layer)
14 Active layer
15 Electron transport layer
16 Second electrode
17 Sealing member
20 CMOS transistor substrate
30 Interlayer insulating film
32 Interlayer wiring portion
40 Sealing layer
42 Scintillator
44 Reflective layer
46 Protective layer
50 Color filter
100 Fingerprint detection unit
200 Display panel unit
200a Display area
220 Organic EL element
230 Touch sensor panel
240 Sealing substrate
300 Vein detection unit
302 Glass substrate
304 Light source portion
306 Cover portion
310 Insertion portion
400 Image detection unit for TOF type distance measuring device
402 Floating diffusion layer
404 Photo-gate
406 Light shielding portion

1. A photoelectric conversion element comprising:
a pair of electrodes;
an active layer provided between the pair of electrodes and including a p-type semiconductor (P); and
a buffer layer provided between one of the pair of electrodes and the active layer and including a dielectric (D),
wherein the dielectric (D) has a band gap of 4 eV or more and a relative permittivity of 20 or more, and
wherein the photoelectric conversion element satisfies the following Expression (1):
$$Ec - E ( L ) > 0.8 eV \qquad ( 1 )$$
in Expression (1), Ec represents an energy level at a lower end of a conduction band of the dielectric (D), and E(L) represents a LUMO energy level of the p-type semiconductor (P).

2. The photoelectric conversion element according to claim 1, wherein the dielectric (D) is an oxide including one or more selected from the group consisting of hafnium oxide, zirconium oxide, and tantalum oxide.

3. The photoelectric conversion element according to claim 1, wherein the p-type semiconductor (P) is a conjugated polymer compound.

4. The photoelectric conversion element according to claim 1, wherein the p-type semiconductor (P) is a polymer compound containing a structural unit represented by the following Formula (I) and/or a structural unit represented by the following Formula (II): 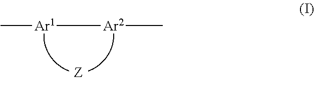
in Formula (I), Ar¹ and Ar² each independently represent a trivalent aromatic heterocyclic group which may have a substituent, and Z represents a group represented by any one of the following Formulas (Z-1) to (Z-7): 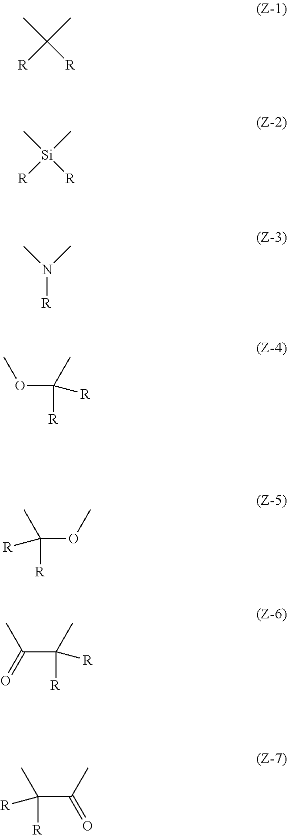
in Formulas (Z-1) to (Z-7), R represents
a hydrogen atom,
a halogen atom,
an alkyl group which may have a substituent,
a cycloalkyl group which may have a substituent,
an alkenyl group which may have a substituent,
a cycloalkenyl group which may have a substituent,
an alkynyl group which may have a substituent,
a cycloalkynyl group which may have a substituent,
an aryl group which may have a substituent,
an alkyloxy group which may have a substituent,
a cycloalkyloxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an imine residue which may have a substituent,
an amide group which may have a substituent,
an acid imide group which may have a substituent,
a substituted oxycarbonyl group which may have a substituent,
a cyano group,
a nitro group,
a group represented by —C(═O)—R^{c}, or
a group represented by —SO₂—R^{d}, and
R^{c} and R^{d} each independently represent
a hydrogen atom,
an alkyl group which may have a substituent,
a cycloalkyl group which may have a substituent,
an aryl group which may have a substituent,
an alkyloxy group which may have a substituent,
a cycloalkyloxy group which may have a substituent,
an aryloxy group which may have a substituent, or
a monovalent heterocyclic group which may have a substituent, and
in Formulas (Z-1) to (Z-7), when the number of R's is two, the two R's may be the same as or different from each other,
—Ar³— (II)
in Formula (II), Ar³ represents a divalent aromatic heterocyclic group.

5. The photoelectric conversion element according to claim 1, wherein the photoelectric conversion element is used for a photodetector.
